(19) United States
(12) Patent Application Publication
(10) Pub. No.: US 2018/0175315 A1
(43) Pub. Date: Jun. 21, 2018

(54) GAS BARRIER FILM, TRANSPARENT ELECTROCONDUCTIVE MEMBER, AND ORGANIC ELECTROLUMINESCENCE ELEMENT, AND METHOD FOR PRODUCING GAS BARRIER FILM, METHOD FOR PRODUCING TRANSPARENT ELECTROCONDUCTIVE MEMBER, AND METHOD FOR PRODUCING ORGANIC ELECTROLUMINESCENCE ELEMENT

(71) Applicant: Konica Minolta, Inc., Tokyo (JP)

(72) Inventors: Shusaku KON, Hino-shi, Tokyo (JP); Takaaki KUROKI, Hachioji-shi, Tokyo (JP); Yasunobu KOBAYASHI, Hachioji-shi, Tokyo (JP)

(21) Appl. No.: 15/738,473

(22) PCT Filed: Mar. 18, 2016
(86) PCT No.: PCT/JP2016/058809

§ 371 Date: Dec. 20, 2017

(30) Foreign Application Priority Data
Jun. 24, 2015 (JP) 2015-126866

(51) Int. Cl. H01L 51/50; B32B 9/00; H05B 33/04; H05B 33/10; H05B 33/28

(52) U.S. Cl. CPC H01L 51/50; B32B 9/00; H05B 33/28; H05B 33/10; H05B 33/04

(57) ABSTRACT

An organic EL element includes a gas barrier film including: a resin base material; a light scattering layer provided on the resin base material; a smoothing layer provided on the light scattering layer; and a gas barrier layer provided on the smoothing layer, wherein the arithmetic average roughness (Ra) of the surface of the gas barrier layer is from 0 nm to 3 nm, and the average of the diameters in the planar direction of the convexities formed on the surface of the gas barrier layer is 50 nm or larger.

### TECHNICAL FIELD

The present invention relates to a gas barrier film having a light extraction layer and a gas barrier layer, a transparent electroconductive member using this gas barrier film, and an organic electroluminescence element including this transparent electroconductive member, and a method for producing a gas barrier film having a light extraction layer and a gas barrier layer, a method for producing a transparent electroconductive member, and a method for producing an organic electroluminescence element.

### BACKGROUND ART

In recent years, in the field of electronic devices, there is an increasing demand for high long-term reliability, a high degree of freedom of shape, capability of curved display, and the like, in addition to the demand for weight reduction and increase in size. Thus, resin base materials such as transparent plastics begin to be employed instead of glass substrates that are heavy, easily crack, and are not apt for area enlargement.

However, resin base materials such as transparent plastics have a problem that the resin base materials have inferior gas barrier properties compared to glass substrates. It is known that when a substrate having inferior gas barrier properties is used, water vapor or oxygen penetrates into the substrate and, for example, deteriorates the functions of the inner components of an electronic device.

Thus, it is generally known that a film having gas barrier properties (gas barrier layer) is formed on a resin base material, and this is used as a gas barrier film. For example, it has been suggested to form, on a resin base material, a gas barrier layer including inorganic layers and organic layers disposed between the inorganic layers (see, for example, Patent Literature 1).

Furthermore, in regard to organic electroluminescence (EL) elements, which constitute one class of electronic devices, it is also known that in order to increase the luminescence efficiency, a configuration in which a light extraction layer formed from a light scattering layer is provided is effective.

However, when a gas barrier layer or a light extraction layer is formed on a resin base material, concavities and convexities are produced on the surface, and as a result, on an occasion of forming a light emitting unit having an organic functional layer as an upper layer thereon, deterioration of storability in a high-temperature high-humidity atmosphere or short circuit (electrical short circuit) is likely to occur, and there is a problem with a decrease in reliability.

Furthermore, in a case where a light extraction layer is formed on a resin base material, the impurities remaining in this light extraction layer or the gas barrier layer exert adverse effects on the organic functional layer. Basically, organic EL elements are known to be very sensitive to trace amounts of moisture, oxygen, and other organic materials (residual solvents and the like), and a configuration having a gas barrier layer immediately below the organic functional layer has also been suggested (see, for example, Patent Literature 2).

### CITATION LIST

### Patent Literature

Patent Literature 1: JP 2014-510373 A

Patent Literature 2: JP 2004-319331 A

### SUMMARY OF INVENTION

### Technical Problem

As described above, in regard to electronic instruments such as organic EL elements, it is required that a balance is achieved between the light extraction efficiency and reliability. An object of the present invention is to provide a gas barrier film capable of increasing the light extraction efficiency and reliability, a transparent electroconductive member, and an organic electroluminescence element, and a method for producing a gas barrier film, a method for producing a transparent electroconductive member, and a method for producing an organic electroluminescence element.

### Solution to Problem

The gas barrier film of the present invention includes a resin base material, a light scattering layer provided on the resin base material, a smoothing layer provided on the light scattering layer, and a gas barrier layer provided on the smoothing layer. Furthermore, the arithmetic average roughness (Ra) of the surface of the gas barrier layer is from 0 nm to 3 nm, and the average of the diameter in the planar direction of the convexities formed on the surface of the gas barrier layer is 50 nm or larger.

The transparent electroconductive member of the present invention includes an electroconductive layer on the gas barrier film. The organic electroluminescence element of the present invention includes a first electrode, a light emitting unit, and a second electrode on the gas barrier film.

The method for producing a gas barrier film of the present invention includes a step of forming a light scattering layer on a resin base material; a step of forming a smoothing layer on the light scattering layer; and a step of forming a gas barrier layer in which the arithmetic average roughness (Ra) of the surface is from 0 nm to 3 nm and the average of the diameters in the planar direction of the convexities formed at the surface is 50 nm or more, on the smoothing layer. The step of forming a gas barrier layer is carried out using a dry process with a film-forming rate of from 150 nm/min to 250 m/min. Alternatively, the gas barrier layer is formed through a step of modifying a polysilazane and forming a first gas barrier layer containing silicon oxynitride, and a step of forming a second gas barrier layer containing niobium oxide using a sputtering method, on the first gas barrier layer.

Furthermore, the method for producing a transparent electroconductive member of the present invention includes a step of forming an electroconductive layer on the gas barrier film. The method for producing an organic electroluminescence element of the present invention includes a step of forming a first electrode, a light emitting unit, and a second electrode on the gas barrier film.

### Advantageous Effects of Invention

According to the present invention, a gas barrier film capable of increasing the light extraction efficiency and reliability, a transparent electroconductive member, and an organic electroluminescence element, and a method for producing a gas barrier film, a method for producing a transparent electroconductive member, and a method for producing an organic electroluminescence element, can be provided.

### BRIEF DESCRIPTION OF DRAWINGS

FIG. 1 is a diagram illustrating an outline configuration of a gas barrier film.

FIG. 2 is a SEM image of the surface of a gas barrier layer (film-forming rate: 200 nm/min).

FIG. 3 is a SEM image of the surface of a gas barrier layer (film-forming rate: 350 nm/min).

FIG. 4 is a schematic diagram of a cross-section.

FIG. 5 is a diagram illustrating an apparatus for producing a gas barrier layer.

FIG. 6 is a graph showing the various elemental profiles in the thickness direction of a gas barrier layer.

FIG. 7 is a diagram illustrating an outline configuration of a transparent electroconductive member.

FIG. 8 is a diagram illustrating an outline configuration of an organic EL element.

### DESCRIPTION OF EMBODIMENTS

Hereinafter, exemplary embodiments for carrying out the present invention will be described; however, the present invention is not intended to be limited to the following exemplary embodiments.

The description will be given in the following order.

1. Gas barrier film

2. Method for producing gas barrier film

3. Transparent electroconductive member

4. Method for producing transparent electroconductive member

5. Organic electroluminescence element

6. Method for producing organic electroluminescence element

<1. Gas Barrier Film>

In the following description, embodiments of a gas barrier film will be described. The gas barrier film includes at least a resin base material, a light extraction layer composed of at least a light scattering layer and a smoothing layer provided on the resin base material, and a gas barrier layer provided on this light extraction layer. In the gas barrier layer, the arithmetic average roughness (Ra) of the surface is from 0 nm to 3 nm, and the average of the diameters in the planar direction of the convexities formed at the surface is 50 nm or more.

It is preferable that such a gas barrier layer contains at least one or more selected from silicon nitride (SiN) and silicon oxynitride (SiON).

Furthermore, it is preferable that a configuration in which a layer containing at least one or more selected from silicon nitride (SiN) and silicon oxynitride (SiON) is used as a first gas barrier layer, and a second gas barrier layer containing niobium oxide (NbO) is provided on this first gas barrier layer, is adopted. Particularly, in a case where a layer containing silicon oxynitride (SiON) is produced by a wet process as the first gas barrier layer, it is preferable that a configuration in which a second gas barrier layer containing niobium oxide (NbO) is provided on the first gas barrier layer containing silicon oxynitride (SiON), is adopted.

It is preferable that the haze value (proportion of the scattering transmittance with respect to the total light transmittance) of a laminate of the resin base material, the light extraction layer, and the gas barrier layer is from 30% to 75%.

Meanwhile, the term “transparency” means that the total light transmittance in the visible light wavelength region measured by a method equivalent to RS K 7361-1:1997 (Plastics—Determination of the total luminous transmittance of transparent materials), is 70% or higher.

The refractive index can be measured using, for example, a spectroscopic ellipsometer, alpha-SE, manufactured by J.A. Woollam Japan Corp.

The haze value is a physical property value calculated under (i) the influence of the difference between the refractive indices of the compositions in the film, and (ii) the influence of the surface shape. That is, the haze value excluding the influence caused by the item (ii) can be measured by suppressing the surface roughness to be lower than a certain level and measuring the haze value. Specifically, the haze value can be measured using a haze meter (manufactured by Nippon Denshoku Industries Co., Ltd., NDH-5000 or the like).

The arithmetic average roughness Ra of the surface means the arithmetic average roughness according to JIS B 0601-2001. The surface roughness (arithmetic average roughness Ra) was calculated from a profile curve of concavities and convexities continuously measured with a detector having a probe having a minuscule tip radius using an atomic force microscope (AFM) manufactured by Digital Instruments, Inc., measurement was made three times within a zone of 10 μm in the direction of measurement using the probe having a minuscule tip radius, and the surface roughness was determined from the average roughness related to the amplitude of fine concavities and convexities.

A main component refers to a component occupying the highest proportion in the composition.

[Configuration of Gas Barrier Film]

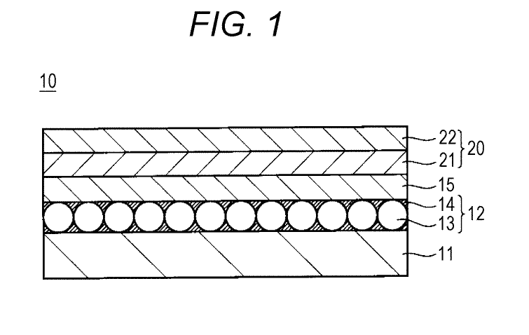

Hereinafter, various configurations of the gas barrier film will be described by taking a gas barrier film having the configuration illustrated in FIG. 1 as an example.

FIG. 1 illustrates an outline configuration of the gas barrier film 10 of the present embodiment. The gas barrier film 10 illustrated in FIG. 1 has a configuration in which a resin base material 11; a light extraction layer composed of a light scattering layer 12 and a smoothing layer 15 provided on the resin base material 11; and a gas barrier layer 20 formed on the light extraction layer, are laminated in this order. The gas barrier film 10 satisfies the requirements that the surface of the gas barrier layer 20 has an arithmetic average roughness (Ra) of from 0 nm to 3 nm, and the average of the diameters in the planar direction of the convexities formed at the surface is 50 nm or more.

Furthermore, the gas barrier film 10 illustrated in FIG. 1 is configured such that the gas barrier layer 20 has a first gas barrier layer 21 containing at least one or more selected from silicon nitride (SiN) and silicon oxynitride (SiON), and a second gas barrier layer 22 containing niobium oxide (NbO) formed in order from the resin base material 11 side. Therefore, in regard to the gas barrier film 10, the surface of the second gas barrier layer 22 containing niobium oxide (NbO) needs to satisfy the requirements that the arithmetic average roughness (Ra) is from 0 nm to 3 nm, and the average of the diameters in the planar direction of the convexities formed at the surface is 50 nm or more.

Preferably, it is preferable that the surface of the first gas barrier layer 21 containing at least one or more selected from silicon nitride (SiN) and silicon oxynitride (SiON) satisfies the requirements that the arithmetic average roughness (Ra) is from 0 nm to 3 nm, and the average of the diameters in the planar direction of the convexities formed at the surface is 50 nm or more, and the second gas barrier layer 22 containing niobium oxide (NbO) satisfies the requirements of Ra and the diameters in the planar direction of convexities.

[Resin Base Material]

The resin base material 11 used for the gas barrier film 10 may be, for example, a resin film; however, the resin base material is not limited to this. A resin base material 11 that is preferably used may be a transparent resin film.

Examples of the resin film include polyesters such as polyethylene terephthalate (PET) and polyethylene naphthalate (PEN); polyethylene, polypropylene; cellulose esters such as Cellophane, cellulose diacetate, cellulose triacetate (TAC), cellulose acetate butyrate, cellulose acetate propionate (CAP), cellulose acetate phthalate, and cellulose nitrate, or derivatives thereof; polyvinylidene chloride, polyvinyl alcohol, polyethylene vinyl alcohol, syndiotactic polystyrene, polycarbonate, a norbornene resin, polymethylpentene, polyether ketone, polyimide, polyether sulfone (PES), polyphenylene sulfide, a polysulfone, polyether imide, polyether ketone imide, polyimide, a fluororesin, nylon, polymethyl methacrylate, an acrylic or polyallylate; and cycloolefin-based resins such as ATON (manufactured by JSR Corp.) or APEL (manufactured by Mitsui Chemicals, Inc.)

[Light Extraction Layer]

The light extraction layer has at least a light scattering layer 12 and a smoothing layer 15. The light scattering layer 12 has a binder 14, which is a layer medium, and light scattering particles 13 included in the layer medium. The light extraction layer is a layer causing light scattering by means of a mixture, by utilizing the difference between the refractive indices of the binder 14 and the light scattering particles 13 having a higher refractive index than that of the binder 14. The smoothing layer 15 is a layer provided in order to flatten the concavities and convexities of the surface of the light scattering layer 12.

[Light Extraction Layer: Light Scattering Layer]

In the gas barrier film 10, in a case where light penetrates from the gas barrier layer 20 in the direction of the resin base material 11, the light transmitted by the gas barrier film 10 passes through the smoothing layer 15 and enters the light scattering layer 12. In this case, it is desirable that the average refractive index ns of the light scattering layer 12 is as close to that of the smoothing layer 15 as possible, and it is preferable that the average refractive index is lower than that of the smoothing layer 15.

It is preferable that the average refractive index ns of the light scattering layer 12 with respect to the shortest maximum wavelength among the maximum wavelengths of the light transmitted by the gas barrier film 10 is preferably in the range of 1.5 or greater and less than 2.5, and more preferably 1.6 or greater and less than 2.3. In this case, in regard to the light scattering layer 12, a film may be formed using a single material having an average refractive index ns of 1.5 or greater and less than 2.5, or a film having an average refractive index ns of 1.5 or greater and less than 2.5 may be formed by mixing two or more kinds of compounds. In the case of such a mixed system, regarding the average refractive index ns of the light scattering layer 12, a calculated refractive index calculated based on the sum total value obtained by multiplying the intrinsic refractive indices of the respective materials by the mixing ratio and adding up the products, is used. Furthermore, in this case, the refractive index of each of the materials may be less than 1.5 or 2.5 or greater, and it is acceptable as long as the average refractive index ns of the mixed film satisfies the condition of being 1.5 or greater and less than 2.5.

Here, in a case where the film is formed from a single material, the “average refractive index ns” is the refractive index of the single material, and in the case of a mixed system, the “average refractive index ns” is the calculated refractive index computed based on the sum total value obtained by multiplying the intrinsic refractive indices of the respective materials by the mixing ratio and adding up the products.

The binder 14 has a refractive index nb of less than 1.9, and a binder having a refractive index nb of less than 1.6 is particularly preferred. In a case where the binder 14 is formed from a single material, the refractive index nb thereof is the refractive index of the single material, and in the case of a mixed system, the refractive index nb is the calculated refractive index computed based on the sum total value obtained by multiplying the intrinsic refractive indices of the respective materials by the mixing ratio and adding up the products.

The light scattering particles 13 has a refractive index np of from 1.5 to 3.0, and it is preferable that the refractive index np is from 1.8 to 3.0, and particularly preferably from 2.0 to 3.0. In a case where the light scattering particles 13 are formed from a single material, the refractive index np thereof is the refractive index of a single material, and in the case of a mixed system, the refractive index np is the calculated refractive index computed based on the sum total value obtained by multiplying the intrinsic refractive indices of the respective materials by the mixing ratio and adding up the products.

As a role of the light scattering particles 13 having a high refractive index in the light scattering layer 12, the function of scattering guided light may be mentioned. For an enhancement of the function of scattering guided light, it is necessary to enhance the scattering performance of the light scattering particles 13. In order to enhance the scattering performance, methods such as increasing the difference between the refractive indices of the light scattering particles 13 and the binder 14, making the layer thickness large, and making the particle density high, may be considered. Among these, the method having the least adverse effects on other functions is the method of increasing the difference between the refractive indices of the light scattering particles 13 and the binder 14.

The difference in the refractive index, |nb−np|, between the refractive index nb of the binder 14 as a layer medium and the refractive index np of the incorporated light scattering particles 13 having a high refractive index is preferably 0.2 or larger, and particularly preferably 0.3 or larger. When the difference in the refractive indices, |nb−np|, between the layer medium and the light scattering particles 13 is 0.03 or larger, a scattering effect occurs at the interface between the layer medium and the light scattering particles 13. As the difference in the refractive index, |nb−np|, is larger, refraction at the interface increases, and the scattering effects are enhanced, which is preferable.

Specifically, since it is preferable to use a high-refractive index material having an average refractive index ns in the range of 1.6 or greater and less than 2.5 is used as the light scattering layer 12, for example, it is preferable to adjust the refractive index nb of the binder 14 to be smaller than 1.6. Furthermore, it is preferable to adjust the refractive index np of the light scattering particles 13 to be greater than 1.8.

The measurement of the refractive index can be carried out similarly to the case of the smoothing layer 15, by irradiating the relevant material with light having the shortest maximum wavelength among the maximum wavelengths of the light transmitted by the gas barrier film in an atmosphere at 25° C., and measuring the refractive index using an Abbe refractometer (manufactured by ATAGO Co., Ltd., DR-M2).

The light scattering layer 12 has an action of diffusing light based on the difference between the refractive indices of the binder 14 as a layer medium and the light scattering particles 13, as described above. For this reason, it is required for the light scattering particles 13 to have less adverse effects on other layers and to have superior characteristics of scattering light.

Here, scattering means a state in which the haze value at a single layer of the light scattering layer 12 (ratio of the scattering transmittance with respect to the total light transmittance) is 50% or higher, more preferably 60% or higher, and particularly preferably 70% or higher. When the haze value is 50% or higher, the light scattering properties can be enhanced.

(Light Scattering Particles)

The light scattering particles 13 are such that the average particle size is preferably 0.2 μm or larger, and preferably less than 1 μm. In regard to the light scattering layer 12, for example, the scattering properties can be enhanced by adjusting the particle size of the light scattering particles 13. Specifically, it is preferable to use transparent particles having a particle size that is larger than or equal to a region causing Mie scattering in the visible light region. When the average particle size of the light scattering particles 13 is 0.2 μm or greater, the light scattering properties can be enhanced.

Meanwhile, regarding the upper limit of the average particle size, in a case where the particle size is larger, it is necessary to make the layer provided on the light scattering layer 12 such as the smoothing layer 15 thick in order to flatten the roughness of the light scattering layer 12 containing the light scattering particles 13, and it is disadvantageous from the viewpoint of the load of processes and the absorption of light by the smoothing layer 15. When the average particle size of the light scattering particles 13 is less than 1 μm, the thickness of the smoothing layer 15 can be suppressed.

In a case where a plurality of kinds of particles are used in the light scattering layer 12, it is preferable that as the other particles excluding the particles described above, the light scattering layer 12 contains at least one kind of particles having an average particle size in the range of 100 nm to 3 μm, and particles having an average particle size of 3 μm or larger are not included. Particularly, it is preferable that the light scattering layer 12 contains at least one kind of particles having an average particle size in the range of 200 nm to 1 μm, and particles having an average particle size of 1 μm or larger are not included.

The average particle size of the light scattering particles 13 can be measured by means of, for example, an apparatus utilizing a dynamic light scattering method, such as NANOTRAC UPA-EX150 manufactured by Nikkiso Co., Ltd., or image processing of electron microscopic photographs.

There are no particular limitations on such light scattering particles 13, and the light scattering particles can be selected as appropriate according to the purpose. The light scattering particles 13 may be organic microparticles or inorganic microparticles. Furthermore, as the material having a high refractive index, quantum dots described in WO 2009/014707 A, U.S. Pat. No. 6,608,439, and the like can also be suitably used. Among them, it is preferable that the light scattering particles 13 are inorganic microparticles having a high refractive index. The refractive index of the light scattering particles 13 is as described above, and the refractive index np is from 1.5 to 3.0, preferably from 1.8 to 3.0, and particularly preferably from 2.0 to 3.0.

Examples of the inorganic microparticles having a high refractive index include polymethyl methacrylate beads, acrylic-styrene copolymer beads, melamine beads, polycarbonate beads, styrene beads, crosslinked polystyrene beads, polyvinyl chloride beads, and benzoguanamine melamine formaldehyde beads.

Examples of the inorganic microparticles having a high refractive index include inorganic oxide particles formed from an oxide of at least one selected from zirconium, titanium, aluminum, indium, zinc, tin, and antimony. Specific examples of the inorganic oxide particles include ZrO₂, TiO₂, BaTiO₃, Al₂O₃, In₂O₃, ZnO, SnO₂, Sb₂O₃, ITO, SiO₂, ZrSiO₄, and zeolite, and among them, TiO₂, BaTiO₃, ZrO₂, ZnO, and SnO₂ are preferred, while TiO₂ is most preferred. Furthermore, among various types of TiO₂, the rutile type is preferred to the anatase type, because since the rutile type has low catalytic activity, the weather resistance of the light scattering layer 12 or an adjacent layer increases, and the refractive index becomes higher.

Regarding these light scattering particles 13, from the viewpoint of enhancing dispersibility or stability in the case of producing the dispersion liquid that will be described below in order to incorporate the light scattering particles into the light scattering layer 12 having a high refractive index, it can be selected whether the light scattering particles should be used after being subjected to a surface treatment, or the light scattering particles should be used without being subjected to a surface treatment.

In the case of performing a surface treatment, specific examples of the material for the surface treatment include inorganic oxides such as silicon oxide and zirconium oxide; metal hydroxides such as aluminum hydroxide; organosiloxanes; and organic acids such as stearic acid. These surface treatment materials may be used singly, or a plurality of kinds may be used in combination. Among them, from the viewpoint of the stability of the dispersion liquid, the surface treatment material is preferably an inorganic oxide and/or a metal hydroxide, and more preferably a metal hydroxide.

In a case where the inorganic oxide particles have been subjected to a surface coating treatment with a surface treatment material, the coating amount (generally, this coating amount is defined as the mass ratio of the surface treatment material used for the surface of the particles with respect to the mass of the particles) is preferably 0.01% to 99% by mass. Generally, the coating amount is defined as the mass ratio of the surface treatment material used for the surface of the particles with respect to the mass of the particles. When the coating amount is adjusted to be in that range, an effect of enhancing dispersibility or stability caused by the surface treatment can be sufficiently obtained, and the light extraction efficiency can be increased by the high refractive index of the light scattering layer 12.

It is preferable that the light scattering particles 13 having a high refractive index is disposed to be in contact with or close to the interface between the light scattering layer 12 and a layer adjacent to thereto, for example, the interface between the light scattering layer 12 and the smoothing layer 15. Thereby, the evanescent light leaking into the light scattering layer 12 when total reflection occurs in the adjacent layer can be scattered by the particles, and the light extraction efficiency is increased.

The content of the light scattering particles 13 in the light scattering layer 12 is, as the volume filling ratio, preferably in the range of 1.0% to 70%, and more preferably in the range of 5.0% to 50%. Thereby, a distribution of the density of the refractive index can be produced with regard to the interface between the light scattering layer 12 and a layer adjacent thereto, and the light extraction efficiency can be increased by increasing the quantity of light scattering.

Regarding the method for forming the light scattering layer 12, for example, when the layer medium (binder) is a resin material, the light scattering layer 12 can be formed by dispersing the light scattering particles 13 in a solution of the resin material (polymer) that serves as a medium, and applying the dispersion on the resin base material 11. In the resin material (polymer) solution, a solvent that does not dissolve the particles is used.

Since the light scattering particles 13 are actually polydisperse particles, or it is difficult to arrange the light scattering particles regularly, the light scattering particles 13 locally have a diffraction effect; however, in many cases, the light extraction efficiency is enhanced by changing the direction of light by diffusion.

(Binder)

Regarding the binder 14 of the light scattering layer 12, the same resin as that of the smoothing layer 15 that will be described below may be mentioned. Furthermore, as the binder used for the light scattering layer 12, a compound from which an oxide, a nitride, or an oxynitride of an inorganic material is formed, or a compound from which an oxide, a nitride, or an oxynitride of a metal is formed, both by irradiation with ultraviolet radiation in a particular atmosphere can be particularly suitably used. Regarding such a compound, a compound that may be subjected to modification at a relatively low temperature as described in JP 8-112879 A is preferred.

Specific examples include a polysiloxane having a Si—O—Si bond (including a polysilsesquioxane), a polysilazane having a Si—N—Si bond, and a polysiloxazane including both a Si—O—Si bond and a Si—N—Si bond. These can be used as mixtures of two or more kinds thereof. Furthermore, a configuration in which another compound is laminated is also applicable.

The layer thickness of the light scattering layer 12 needs to be thick to a certain extent in order to secure an optical path length for causing scattering; however, on the other hand, the layer thickness needs to be thin to the extent that the layer would not bring about an energy loss caused by absorption. Specifically, the layer thickness is preferably in the range of 0.1 to 2 μm, and more preferably in the range of 0.2 to 1 μm.

(Polysiloxane)

The polysiloxane used for the light scattering layer 12 includes R₃SiO_{1/2}, R₂SiO, RSiO_{3/2}, and SiO₂ as general structural units. Here, R's are independently selected from the group consisting of a hydrogen atom; an alkyl group containing 1 to 20 carbon atoms, for example, methyl, ethyl, or propyl; an aryl group, for example, phenyl; and an unsaturated alkyl group, for example, vinyl. Particular examples of a polysiloxane group include PhSiO_{3/2}, MeSiO_{3/2}, HSiO_{3/2}, MePhSiO, Ph₂SiO, PhViSiO, ViSiO_{3/2}, MeHSiO, MeViSiO, Me₂SiO, and Me₃SiO_{1/2}. Furthermore, a mixture of polysiloxanes or a copolymer can also be used. Vi represents a vinyl group.

(Polysilsesquioxane)

In regard to the light scattering layer 12, it is preferable to use a polysilsesquioxane among the polysiloxanes described above. A polysilsesquioxane is a compound containing silsesquioxane in a structural unit. “silsesquioxane” is a compound represented by the formula: RSiO_{3/2} and is usually represented by the formula: RSiX₃ (wherein R represents a hydrogen atom, an alkyl group, an alkenyl group, an aryl group, an ar-alkyl group (also referred to as aralkyl group), wherein X represents a halogen, an alkoxy group, or the like).

Regarding the shape of the molecular arrangement of the polysilsesquioxane, representative examples that are known include an amorphous structure, a ladder-like structure, a cage-like structure, and partially cleaved structures thereof (a structure resulting from exclusion of one silicon atom from a cage-like structure, or a structure resulting from cutting of some silicon-oxygen bonds of a cage-like structure).

Among these polysilsesquioxanes, it is preferable to use a so-called hydrogen silsesquioxane polymer. An example of the hydrogen silsesquioxane polymer may be a hydridosiloxane polymer represented by HSi(OH)ₓ(OR)_{y}O_{z/2}. R's each represent an organic group or a substituted organic group, and in a case where R is bonded to silicon by an oxygen atom, R forms a hydrolyzable substituent. The following conditions are met: x=0 to 2, y=0 to 2, z=1 to 3, and x+y+z=3. Examples of R include an alkyl group (for example, a methyl group, an ethyl group, a propyl group, or a butyl group), an aryl group (for example, a phenyl group), and an alkenyl group (for example, an allyl group or a vinyl group). These resins are completely condensed to form (HSiO_{3/2})ₙ, or are only partially hydrolyzed (that is, including some Si—OR moieties) and/or partially condensed (that is, including some Si—OH moieties).

(Polysilazane)

The polysilazane used for the light scattering layer 12 is a polymer having silicon-nitrogen bonds, and is an inorganic precursor polymer of SiO₂, Si₃N₄, and an intermediate solid solution of the two, SiOₓN_{y} (x=0.1 to 1.9 and y=0.1 to 1.3), all of which are composed of Si—N, Si—H, N—H, and the like.

Regarding the polysilazane preferably used for the light scattering layer 12, a polysilazane represented by the following General Formula (1) can be used.

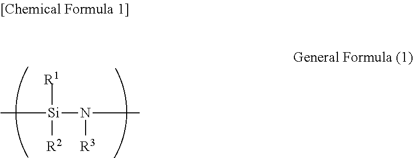

In the formula, R¹, R², and R³ each represent a hydrogen atom, an alkyl group, an alkenyl group, a cycloalkyl group, an aryl group, an alkylsilyl group, an alkylamino group, or an alkoxy group.

From the viewpoint of the compactness as a film of the light scattering layer 12 thus obtained, perhydropolysilazane (PHPS) in which all of R¹, R², and R³ of General Formula (1) represent hydrogen atoms is particularly preferred. Perhydropolysilazane is assumed to have a structure in which a straight-chained structure and a cyclic structure based on a 6-membered ring and an 8-membered ring exist, and perhydropolysilazane is a liquid or solid substance having a molecular weight of about 600 to 2,000 as the number average molecular weight (Mn) (measured by gel permeation chromatography and calculated relative to polystyrene standards).

Polysilazanes are commercially available in the form of a solution in which a polysilazane is dissolved in an organic solvent, and a commercially available product can be directly used as a polysilazane-containing coating liquid. Examples of commercially available products of a polysilazane solution include NN120-20, NAX120-20, and NL120-20 manufactured by AZ Electronic Materials plc.

An ionizing radiation-curable resin composition can be used as the binder 14, and regarding the method for curing an ionizing radiation-curable resin composition, such a resin composition can be cured by a conventional curing method for an ionizing radiation-curable resin composition, that is, irradiation with an electron beam or ultraviolet radiation

For example, in the case of curing with an electron beam, electron beams with 10 to 1,000 keV, and preferably 30 to 300 keV, of energy that is emitted from various electron beam accelerators such as Cockroft-Walton type, Van de Graaff type, resonance transformation type, insulation core transformer type, linear type, Dynamitron type, and high frequency type electron beam accelerators are used. In the case of ultraviolet radiation curing, ultraviolet radiation emitted from the light rays of an ultrahigh pressure mercury lamp, a high pressure mercury lamp, a low pressure mercury lamp, a carbon arc, a xenon arc, a metal halide lamp, and the like can be utilized.

(Vacuum Ultraviolet Irradiation Apparatus having Excimer Lamp)

Regarding the ultraviolet irradiation apparatus, for example, a noble gas excimer lamp that emits vacuum ultraviolet radiation in the range of 100 to 230 nm may be mentioned.

Since the atoms of noble gases such as xenon (Xe), krypton (Kr), argon (Ar) and neon (Ne) are referred to as inert gases because those atoms do not undergo chemical bonding to produce molecules. However, the atoms of noble gases that have obtained energy by discharge or the like (excited atoms) can be bonded to other atoms and produce molecules.

For example, in a case where the noble gas is Xe (xenon), as illustrated by the following reaction formulae, when excited excimer molecules Xe₂* are transitioned into the ground state, Xe₂* emits excimer light at 172 nm.

e+Xe→Xe*

Xe*+2Xe→Xe₂*+Xe

Xe₂*→Xe+Xe+hv(172 nm)

A feature of an excimer lamp is that emission is concentrated on a single wavelength, light other than necessary light is not almost emitted, and therefore, the efficiency is high. Furthermore, since any extra light is not emitted, the temperature of the object can be maintained relatively low. Also, since start-up and restart-up do not require time, instantaneous switching on and off is enabled.

An example of a light source that efficiently emits excimer light may be a dielectric barrier discharge lamp.

A dielectric barrier discharge lamp is configured so as to cause discharge by means of a dielectric disposed between electrodes, and generally, it is desirable that at least one of the electrodes is disposed in a discharge vessel formed from a dielectric and in the outside of the vessel. An example of the dielectric barrier discharge lamp is a lamp in which a noble gas such as xenon is encapsulated in a double cylinder type discharge vessel composed of a large tube and a small tube, both formed from quartz glass, and the discharge vessel is provided with a network-like first electrode in the outside and is provided with another electrode in the inside of the inner tube. A dielectric barrier discharge lamp produces dielectric barrier discharge inside the discharge vessel by applying a high frequency voltage between electrodes, and generates excimer light when excimer molecules of xenon and the like produced by this discharge are dissociated.

Since an excimer lamp has high light generation efficiency, it is possible to turn on the excimer lamp with low power supply. Also, since an excimer lamp does not emit light having a long wavelength that is causative of temperature increase, and radiates energy at a single wavelength in the ultraviolet region, an excimer lamp has a feature that the temperature increase in an object of irradiation caused by the emitted light itself is suppressed.

Meanwhile, in order to further incorporate the light that has been introduced into a layer adjacent to the light scattering layer 12, into the light scattering layer 12, it is preferable that the difference between the refractive indices of the binder 14 of the light scattering layer 12 and the adjacent layer is small. Specifically, it is preferable that the difference between the refractive indices of the binder 14 of the light scattering layer 12 and the adjacent layer is 0.1 or less. It is also preferable that the material that constitutes the adjacent layer and the binder 14 included in the light scattering layer 12 are of the same material.

[Light Extraction Layer: Smoothing Layer]

A smoothing layer 15 is provided mainly for the purpose of preventing harmful effects such as deterioration of storability in a high-temperature and high-humidity atmosphere and electrical short circuit (short circuit), which are caused by the surface unevenness of the light scattering layer 12. The smoothing layer 15 is provided between the light scattering layer 12 and the gas barrier layer 20.

In the smoothing layer 15, the light transmitted by the gas barrier layer 20 enters the smoothing layer. Therefore, it is preferable that the average refractive index nf of the smoothing layer 15 has a value close to that of the refractive index of the gas barrier layer 20. Specifically, in a case where the average refractive index nc of the gas barrier layer 20 is from 1.7 to 3.0 as will be described below, it is preferable that the smoothing layer 15 is a high-refractive index layer having an average refractive index nf of 1.5 or higher, and particularly higher than 1.65 and lower than 2.5, with respect to the shortest maximum emission wavelength among the maximum wavelengths of the light transmitted by the gas barrier film 10. As long as the average refractive index nf is higher than 1.65 and lower than 2.5, the smoothing layer 15 may be formed from a single material or may be formed from a mixture. In the case of such a mixed system, regarding the average refractive index nf of the smoothing layer 15, a calculated refractive index computed based on the sum total value obtained by multiplying the intrinsic refractive indices of the respective materials by the mixing ratio and adding up the products, is used. Furthermore, in this case, the refractive indices of the respective materials may be 1.65 or lower or 2.5 or higher, and it is acceptable as long as the average refractive index of of the mixed film satisfies the condition of being higher than 1.65 and lower than 2.5.

Regarding the smoothing layer 15, a high-refractive index smoothing layer obtained by incorporating high-refractive index nanoparticles into a resin formed by a wet process or a resin that serves as a layer medium (binder), an inorganic film formed by a dry process, or the like can be used.

Regarding the inorganic film formed by a dry process, for example, nitride, oxide, oxynitride and the like of silicon or a metal can be used. Among them, it is preferable to use silicon nitride (SiN) when the gas barrier properties, productivity, and the combination with the reaction product of an organosilicon compound or a silicon oxynitride compound are considered.

Regarding the resin used for the smoothing layer 15 and the resin that serves as a layer medium (binder), any known resin can be used without any particular limitations, and examples include an acrylic acid ester, a methacrylic acid ester, polyethylene terephthalate (PET), polybutylene terephthalate, polyethylene naphthalate (PEN), polycarbonate (PC), polyallylate, polyvinyl chloride (PVC), polyethylene (PE), polypropylene (PP), polystyrene (PS), nylon (Ny), an aromatic polyimide, a poly ether ether ketone, a polysulfone, a polyether sulfone, a polyimide, a polyether imide; a silsesquioxane, a polysiloxane, a polysilazane, a polysiloxazane, and a perfluoroalkyl group-containing silane compound (for example, (heptadecafluoro-1,1,2,2-tetradecyl)triethoxysilane), all of which have an organic-inorganic hybrid structure; and a fluorine-containing copolymer having a fluorine-containing monomer and a monomer for imparting a crosslinkable group as constituent units. These resins can be used as a mixture of two or more kinds thereof. Among these, a compound having an organic-inorganic hybrid structure is preferred.

It is also possible to use the following hydrophilic resins. Examples of the hydrophilic resins include a water-soluble resin, a water-dispersible resin, a colloidal dispersion resin, and mixtures thereof. Regarding the hydrophilic resins, acrylic, polyester-based, polyimide-based, polyurethane-based, and fluorine-based resins may be mentioned, and examples thereof include polymers such as polyvinyl alcohol, gelatin, polyethylene oxide, polyvinylpyrrolidone, casein, starch, agar, carrageenan, polyacrylic acid, polymethacrylic acid, polyacrylamide, polymethacrylamide, polystyrenesulfonic acid, cellulose, hydroxyethyl cellulose, carboxymethyl cellulose, hydroxyethyl cellulose, dextran, dextrin, pullulan, and water-soluble polyvinyl butyral. However, among these, polyvinyl alcohol is preferred.

The resins used for the smoothing layer 15 may be used singly, or a mixture of two or more kinds thereof may be used as necessary.

Furthermore, similarly, conventionally known resin particles (emulsions) and the like can also be suitably used.

Regarding the resin used for the smoothing layer 15, resins that are cured mainly by ultraviolet radiation and electron beam, that is, a mixture of a ionizing radiation-curable resin, a thermoplastic resin, and a solvent, or a thermosetting resin can also be suitably used.

Regarding such a binder resin, a polymer having a saturated hydrocarbon or a polyether as the main chain is preferred, and a polymer having a saturated hydrocarbon as the main chain is more preferred.

It is preferable that such a resin is crosslinked. It is preferable that the polymer having a saturated hydrocarbon as the main chain is obtained by a polymerization reaction of an ethylenically unsaturated monomer. In order to perform crosslinking and obtain another resin, it is preferable to use a monomer having two or more ethylenically unsaturated groups.

Regarding the high-refractive index nanoparticles used for the smoothing layer 15, nanoparticles described below may be used.

Examples of the nanoparticles having a high refractive index include inorganic oxide particles formed from an oxide of at least one selected from zirconium, titanium, aluminum, indium, zinc, tin, and antimony. Specific examples of the inorganic oxide particles include ZrO₂, TiO₂, BaTiO₃, Al₂O₃, In₂O₃, ZnO, SnO₂, Sb₂O₃, ITO, SiO₂, ZrSiO₄, and zeolite, and among these, TiO₂, BaTiO₃, ZrO₂, ZnO, and SnO₂ are preferred, while TiO₂ is most preferred. Furthermore, among various types of TiO₂, the rutile type is preferred to the anatase type, because since the rutile type has low catalytic activity, the weather resistance of the smoothing layer 15 or an adjacent layer increases, and the refractive index becomes higher.

It is preferable to form a film by incorporating the nanoparticles into the binder as a medium such that the refractive index is in the range of from 1.7 to 3.0. When the refractive index of the nanoparticles is 1.7 or higher, the desired effects can be sufficiently manifested. When the refractive index of the nanoparticles is 3.0 or lower, multiple scattering in the layer is suppressed, and transparency is not easily decreased.

Meanwhile, nanoparticles are defined as fine particles having a particle size in the order of nanometers, which are dispersed in a dispersing medium (colloidal particles). Particles include particles in a state of being individually separated (primary particles), and particles in a state of being aggregated (secondary particles), and nanoparticles are defined to include secondary particles as well.

The lower limit of the particle size of the nanoparticles is usually preferably 5 nm or larger, more preferably 10 nm or larger, and even more preferably 15 nm or larger. The upper limit of the particle size of the nanoparticles is preferably 70 nm or smaller, more preferably 60 nm or smaller, and even more preferably 50 nm or larger. When the particle size of the nanoparticles is in the range of 5 to 60 nm, it is preferable from the viewpoint of obtaining high transparency. The distribution of the particle size is not limited as long as the effects are not impaired, and the particle size distribution may be wide or narrow, or may include a plurality of distributions.

The content of the nanoparticles in the smoothing layer 15 is, as the volume filling ratio, preferably in the range of 1.0% to 90%, and more preferably in the range of 5.0% to 70%. Thereby, a distribution can be produced in the density of the refractive index at the interface between the smoothing layer 15 and the adjacent light scattering layer 12, and the light extraction efficiency can be increased by increasing the quantity of light scattering. Regarding the method for preparing a titanium dioxide sol, for example, JP 63-17221 A, JP 7-819 A, JP 9-165218 A, JP 11-43327 A, and the like can be referred to.

The layer thickness of the smoothing layer 15 needs to be thick to a certain extent in order to relieve the surface roughness of the light scattering layer 12; however, the layer thickness needs to be thin to the extent that energy loss caused by absorption does not occur. The film thickness of the smoothing layer 15 is preferably 10 to 1,000 nm, more preferably 20 to 700 nm, and particularly preferably 30 to 400 nm.

Regarding the method for forming the smoothing layer 15, for example, the smoothing layer 15 can be produced by mixing, after the light scattering layer 12 is formed, a resin solution with a dispersion liquid in which TiO₂ nanoparticles are dispersed, filtering the mixture through a filter, obtaining a smoothing layer-producing solution, subsequently applying the smoothing layer-producing solution on the light scattering layer 12, drying the solution, and then irradiating the dried solution with ultraviolet radiation

[Gas Barrier Layer]

It is important that the gas barrier layer 20 has the flatness, by which another layer can be satisfactorily formed thereon, and regarding the surface characteristics, the arithmetic average roughness (Ra) is from 0 nm to 3 mm. When the arithmetic average roughness Ra is adjusted to be in the range of from 0 nm to 3 nm, defects such as short circuit in the organic EL element to be laminated thereon can be suppressed. In regard to the arithmetic average roughness Ra, 0 nm is preferred; however, as the limit value for a practically useful level, the lower limit is about 0.3 mm. The arithmetic average roughness (Ra) is a value measured by a method according to JIS B0601 (2001).

Furthermore, in regard to the gas barrier layer 20, the average of the diameters in the planar direction of the convexities formed at the surface is 50 nm or larger.

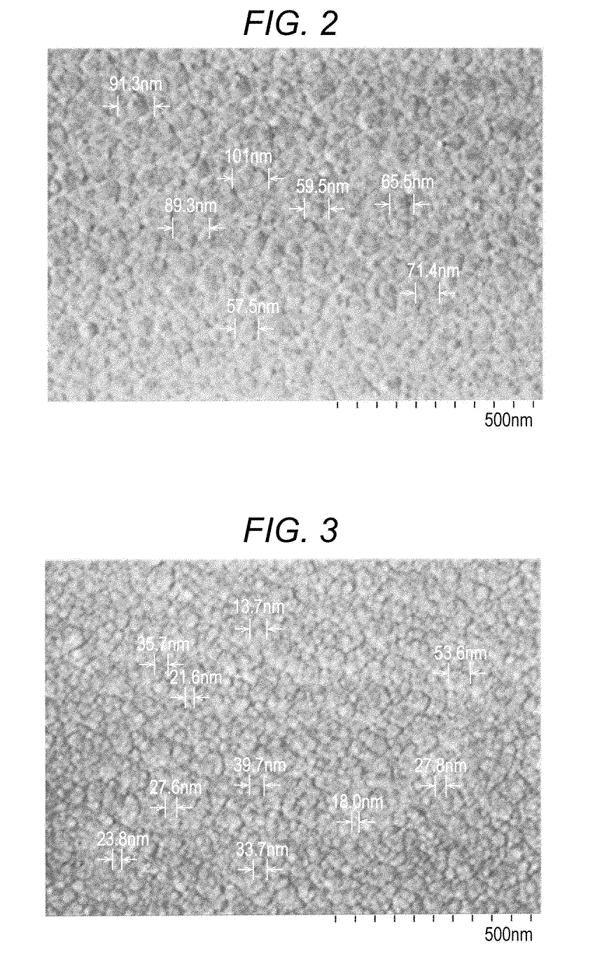

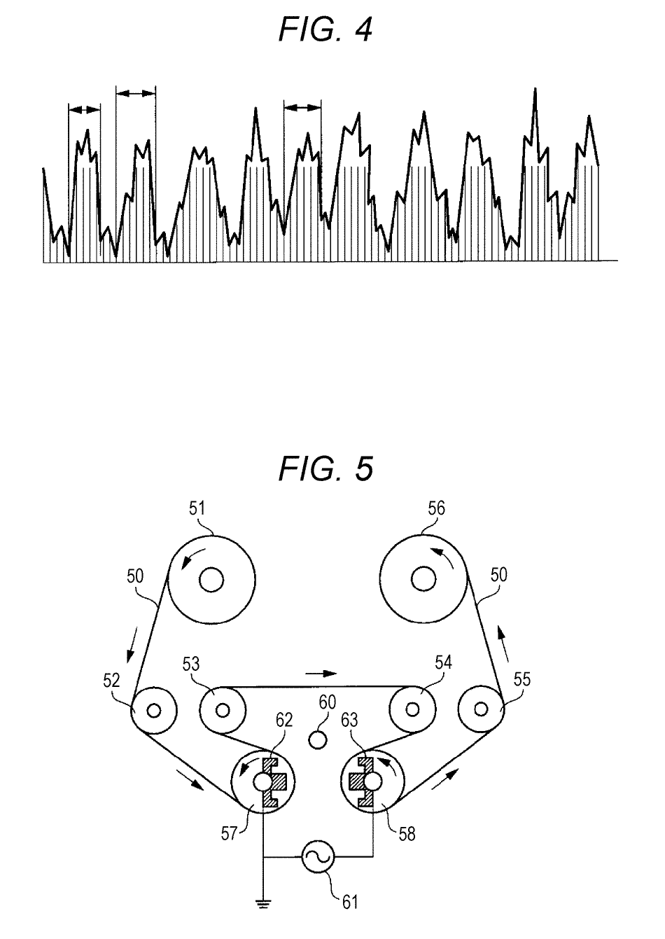

At the time of forming the gas barrier layer 20, as the material that constitutes the gas barrier layer 20 aggregates and grows, minute bump-like grain aggregates are produced on the surface of the gas barrier layer 20. As these minute bump-like grain aggregates are produced, minute convexities (peaks) and concavities (valleys) between these convexities are formed on the surface of the gas barrier layer 20. SEM images of the surface of the gas barrier layer 20 having such convexities formed thereon are presented in FIG. 2 and FIG. 3. A schematic cross-sectional view of this gas barrier layer 20 is presented in FIG. 4.

As shown in FIG. 2 and FIG. 3, the surface of the gas barrier layer 20 has a plurality of convexities (peaks) and a plurality of concavities (valleys) formed thereon as a result of aggregation of the material that constitutes the gas barrier layer 20. Particularly, as a noticeable shape in connection with the gas barrier layer 20, the convexities formed by aggregation are in the form of grain aggregates on the surface of the gas barrier layer 20, and thus convexities in the form of these grain aggregates are formed. When a cross-section of the concavities and convexities of the surface of the gas barrier layer 20 shown in FIG. 2 and FIG. 3 is schematically illustrated, as illustrated in FIG. 4, the entire surface of the gas barrier layer 20 has a shape in which convexities (peaks) and concavities (valleys) are continuously formed.

Regarding the gas barrier layer 20, a highly smooth gas barrier layer can increase reliability as a gas barrier film. Therefore, it is preferable that the surface of the gas barrier layer 20 has a small height of the convexities (peaks). Therefore, in regard to the gas barrier film of the present embodiment, the arithmetic average roughness (Ra) of the surface of the gas barrier layer 20 is defined to be from 0 nm to 3 nm.

Furthermore, in order to increase smoothness of the gas barrier layer 20, it is preferable that not only the height of the convexities (peaks) but also the numbers of the convexities (peaks) and concavities (valleys) are small. That is, a surface shape in which the convexities have grown large and the number of convexities distributed per unit area has been reduced as illustrated in FIG. 4 is preferred to a surface shape in which a large number of minute convexities have been produced and the number of convexities distributed per unit area is large as shown in FIG. 3. Therefore, in regard to the gas barrier film of the present embodiment, the average of the diameters in the planar direction of the convexities formed on the surface of the gas barrier layer 20 is defined to be 50 nm or more.

As the diameters in the planar direction of the convexities on the surface of the gas barrier layer 20 become larger, the number of convexities distributed per unit area is necessarily reduced. Furthermore, under the conditions that satisfy Ra, it is implied that as the diameters in the planar direction of the convexities are larger and the number of distributions of convexities is smaller, the smoothness of the surface of the gas barrier layer 20 increases. That is, theoretically, when the arithmetic average roughness Ra is 0 nm, the above-mentioned convexities are not formed on the surface of the gas barrier layer 20, and the number convexities in a unit area becomes zero. Therefore, the maximum value of the diameters in the planar direction of the convexities thus formed is the length extending over the entirety of the area to be measured (infinity). In such a case, the entire plane within a unit area is regarded as a convexity, and it is considered that the diameter in the planar direction of the convexities satisfies the requirement of being 50 nm or more.

The diameter in the planar direction of convexities on the surface of the gas barrier layer 20 is determined as the average value of unidirectional particle diameters (Feret diameters) of any arbitrary 100 convexities (grain aggregates) using images such as the SEM images shown in FIG. 2 and FIG. 3.

In a case where the gas barrier layer 20 is formed as a single layer, it is desirable that the requirement on the Ra of the surface of the gas barrier layer 20 and the diameters in the planar direction of convexities are satisfied at the surface of this single layer of the gas barrier layer 20. Meanwhile, in a case where the gas barrier layer 20 is formed to be composed of a first gas barrier layer 21 and a second gas barrier layer 22 as illustrated in FIG. 1, it is desirable that the requirements on the Ra and the diameters in the planar direction of convexities are satisfied at the surface side of the gas barrier layer 20, that is, for the surface of the second gas barrier layer 22. As such, when the gas barrier layer 20 is formed as a plurality of layers, it is desirable that the above-described requirements for the surface are satisfied at the surface of the layer that constitutes the outermost surface of the gas barrier layer 20.

Furthermore, in regard to the gas barrier layer 20 in FIG. 1, it is preferable that the surface of the second gas barrier layer 22 satisfies the requirements described above, and also, the surface of the first gas barrier layer 21 satisfies the requirements described above. When the first gas barrier layer 21 satisfies the requirements described above, it is easy to form the surface of the second gas barrier layer 22 formed on this first gas barrier layer 21 into a shape that satisfies the requirements described above. As such, when the gas barrier layer 20 is formed as a plurality of layers, it is preferable that the surface of the layer that is formed on the lower side satisfies the requirements described above, together with the layer that constitutes the outermost surface of the gas barrier layer 20.

In regard to the gas barrier layer 20, it is preferable that the water vapor permeability is less than 0.1 g/(m²·24 h). The water vapor permeability of the gas barrier layer 20 is the value obtained by storing the gas barrier layer under high-temperature and high-humidity conditions at 60° C. and 90% RH, and calculating the amount of moisture that has permeated into the cell from the amount of corrosion of metal calcium based on the method described in JP 2005-283561 A. The gas barrier layer 20 has a water vapor permeability (60±0.5° C., relative humidity 90±2% RH) of less than 0.1 g/(m²·24 h), and the water vapor permeability is preferably 0.01 g/(m²·24 h) or less, and more preferably 0.001 g/(m²·24 h) or less. As illustrated in FIG. 1, when the gas barrier layer 20 is formed to be composed of a first gas barrier layer 21 and a second gas barrier layer 22, it is desirable that the overall permeability of the gas barrier layer 20 satisfies the permeability condition described above.

The refractive index of the gas barrier layer 20 is preferably in the range of 1.7 to 3.0, more preferably in the range of 1.8 to 2.5, and particularly preferably in the range of 1.8 to 2.2. Regarding the refractive index, the value measured at a wavelength of 633 nm at 25° C. with an ellipsometer is handled as a representative value.

Furthermore, it is preferable that the gas barrier layer 20 has a higher refractive index than the various layers that constitute the light extraction layer (light scattering layer 12 and smoothing layer 15), which are layers existing below this gas barrier layer 20. The light transmitted by the gas barrier film 10 penetrates the gas barrier layer 20, the light extraction layer (light scattering layer 12 and smoothing layer 15), and the resin base material 11. Generally, in the resin base material 11, a material having a refractive index that is lower than that of the gas barrier layer 20 is used. Therefore, when the refractive index of the layer provided on the side of the resin base material 11 is relatively small compared to the refractive index of the layer provided on the side of the gas barrier layer 20, reflection of light at the interfaces of the various layers is suppressed, and the light extraction efficiency is increased.

Specifically, it is preferable that the average refractive index nc of the gas barrier layer 20 has a value close to the refractive index of the configuration provided on this gas barrier layer 20, for example, the refractive indices of an electroconductive layer and organic functional layers that constitute a light emitting unit such as an organic EL element. It is preferable that the gas barrier layer 20 is a high refractive index layer having an average refractive index nc of 1.5 or higher, and particularly from 1.8 to 2.5, with respect to the shortest maximum emission wavelength among the maximum emission wavelengths of the light transmitted by the gas barrier film 10. As long as the average refractive index nc is from 1.8 to 2.5, the gas barrier layer may be formed from a single material, or may be formed from a mixture. In the case of such a mixed system, a calculated refractive index computed based on the sum total value obtained by multiplying the intrinsic refractive indices of the respective materials by the mixing ratio and adding up the products is used as the average refractive index nc of the gas barrier layer 20. In this case, the refractive index of the respective materials may be 1.8 or lower or 2.5 or higher, or it is desirable that the average refractive index nc of a mixed film satisfies the requirement of being from 1.8 to 2.5.

Here, the “average refractive index nc” means the refractive index of a single material in a case where the layer is formed from a single material, and in the case of a mixed system, the average refractive index nc is a calculated refractive index computed based on the sum total value obtained by multiplying the intrinsic refractive indices of the respective materials by the mixing ratio and adding up the products. The measurement of the refractive index can be carried out using an Abbe refractometer (manufactured by ATAGO Co., Ltd., DR-M2), by irradiating a gas barrier film with light ray having the shortest maximum wavelength among the maximum wavelengths of the light transmitted by the gas barrier film in an atmosphere at 25° C.

Furthermore, it is preferable that the gas barrier layer 20 has small absorption (value obtained by subtracting a sum value of T % and R % in the integrating sphere-attached spectroscopic measurement of wavelength) in the entire visible light region. In the gas barrier layer 20, the absorption in the entire visible light range of a layer having a thickness of 100 nm is preferably less than 10%, more preferably less than 5%, even more preferably less than 3%, and most preferably less than 1%.

It is preferable that the gas barrier layer 20 includes at least one or more selected from silicon nitride (SiN) and silicon oxynitride (SiON). For example, it is preferable that the gas barrier layer 20 has a first gas barrier layer 21, which is a layer including one or more selected from silicon nitride (SiN) and silicon oxynitride (SiON), and a second gas barrier layer 22 formed on this first gas barrier layer 21, the second gas barrier layer including niobium oxide (NbO).

In a case where the gas barrier layer 20 is formed from a plurality of layers, regarding the gas barrier layer 20, the laminated structure or the order of lamination of the first gas barrier layer 21 containing one or more selected from silicon nitride and silicon oxynitride and the second gas barrier layer 22 containing niobium oxide does not particularly matter. Furthermore, the gas barrier layer 20 may also have a laminated structure of three or more layers, including a plurality of first gas barrier layers 21 containing a silicon oxynitride compound or a plurality of second gas barrier layers 22 containing niobium (Nb). Furthermore, the gas barrier layer 20 may have a gas barrier layer of another configuration, in addition to the first gas barrier layer 21 containing one or more selected from silicon nitride and silicon oxynitride and the second gas barrier layer 22 containing niobium (Nb).

(Gas Barrier Layer: Silicon Nitride)

In a case where the first gas barrier layer 21 is configured as a layer containing silicon nitride (SiN), it is preferable that the silicon nitride (SiN) constituting this layer is formed from a reaction product of an organosilicon compound. A layer containing silicon nitride formed from a reaction product of an organosilicon compound can be formed by, for example, a dry process such as a plasma CVD method or a vapor deposition method, which uses an organosilicon compound in the raw material gas. For the formation of a layer containing silicon nitride using a dry process, it is preferable to use the organosilicon compounds described below as raw material gases.

(Organosilicon Compound)

Examples of the organosilicon compound include metyltrimethoxysilane, dimethyldimethoxysilane, phenyltrimethoxysilane, methyltriethoxysilane, dimethyldiethoxysilane, phenyltriethoxysilane, n-propyltrimethoxysilane, n-propyltriethoxysilane, hexyltrimethoxysilane, hexyltriethoxysilane, octyltriethoxysilane, decyltrimethoxysilane, 1,6-bis(trimethoxysilyl)hexane, trifluoropropyltrimethoxysilane, hexamethyldisilazane, a hydrolysable group-containing siloxane, hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, and octamethylcyclotetrasiloxane. Particularly, from the viewpoint of characteristics such as the ease of handling during film forming and the gas barrier properties of the layer containing an organosilicon compound thus formed, it is preferable to use hexamethyldisiloxane or 1,1,3,3-tetramethyldisiloxane. Furthermore, these organosilicon compounds can be used singly or in combination of two or more kinds thereof.

(Gas Barrier Layer: Silicon Oxynitride)

Silicon oxynitride (SiON) that constitutes the gas barrier layer 20 is obtained by, for example, changing a polysilazane into silicon oxynitride (SiON). Particularly, it is preferable that the silicon oxynitride (SiON) that constitutes the gas barrier layer 20 is formed to include a reaction product of perhydropolysilazane (PHPS). Furthermore, it is preferable that the reaction product of perhydropolysilazane (PHPS) is a product obtained by modifying PHPS by vacuum ultraviolet radiation. Regarding the silicon oxynitride compound, the polysilazane described above in connection with the binder 14 that constitutes the light scattering layer 12 can be used as the polysilazane and perhydropolysilazane (PHPS).

Furthermore, in a case where a layer containing silicon oxynitride (SiON) is produced by a wet process as the first gas barrier layer, it is preferable to adopt a configuration in which the second gas barrier layer 22 containing niobium oxide (NbO) that will be described below is provided to adjoin the first gas barrier layer 21 containing silicon oxynitride (SiON). When the first gas barrier layer 21 formed from silicon oxynitride (SiON) and the second gas barrier layer 22 containing niobium oxide (NbO) are provided at a position where the gas barrier layers are brought into contact, permeation of the gas emitted from the light extraction layer or moisture in the atmosphere through the resin base material 11 can be efficiently prevented, and thus the gas barrier properties of the gas barrier film 10 are further enhanced.

In order to accelerate the change of polysilazane into silicon oxynitride, an amine catalyst, or a metal catalyst such as a Pt compound such as Pt acetylacetonate, a Pd compound such as Pd propionate, or a Rh compound such as Rh acetylacetonate may also be added to the coating liquid. Particularly, it is particularly preferable to use an amine catalyst. Specific examples of the amine catalyst include N,N-diethylethanolamine, N,N-dimethylethanolamine, triethanolamine, triethylamine, 3-morpholinopropylamine, N,N,N′,N′-tetramethyl-1,3-diaminopropane, N,N,N′,N′-tetramethyl-1,6-diaminohexane.

The amount of addition of these catalysts with respect to the polysilazane is preferably in the range of 0.1% to 10% by mass, more preferably in the range of 0.2% to 5% by mass, and even more preferably in the range of 0.5% to 2% by mass, with respect to the total amount of the coating liquid. When the amount of addition of the catalyst is adjusted to be in this range, formation of excess silanol and a decrease in the film density caused by rapid progress of the reaction, an increase in film defects, and the like can be avoided.

(Gas Barrier Layer: Niobium Oxide)

It is preferable that the second gas barrier layer 22 containing niobium (Nb) contains niobium oxide (NbO) as a main component. Furthermore, it is preferable that this second gas barrier layer 22 containing niobium oxide (NbO) as a main component contains niobium oxide having a refractive index of 1.8 or higher as the main component. The second gas barrier layer 22 containing niobium (Nb) is formed on the first gas barrier layer 21 mentioned above so as to be in contact with the first gas barrier layer.

The content of niobium oxide in the second gas barrier layer 22 is preferably 50% by mass or more, more preferably 80% by mass or more, even more preferably 95% by mass or more, particularly preferably 98% by mass or more, and most preferably 100% by mass (that is, the second gas barrier layer 22 is niobium oxide), with respect to the total mass of the second gas barrier layer 22.

The second gas barrier layer 22 may also include nitride, carbide, oxynitride, oxycarbide, and the like of niobium together with niobium oxide. Furthermore, the second gas barrier layer 22 may also include, for example, oxide, nitride, carbide, oxynitride, or oxycarbide of a metal other than niobium.

<2. Method for Producing Gas Barrier Film>

Next, the method for producing a gas barrier film will be described. Here, a method for producing the gas barrier film illustrated in FIG. 1 will be described as an example. Since the various configurations of the gas barrier film, and form examples such as the forming method and conditions for the various configurations are the same as the embodiments described above, a detailed description on the following production method will not be repeated here.

The production of the gas barrier film 10 includes a step of forming a light scattering layer 12 on a resin base material 11, a step of forming a smoothing layer 15 on the light scattering layer 12, and a step of forming a gas barrier layer 20 on the smoothing layer 15. Furthermore, in the production of the gas barrier film 10, the step of forming a gas barrier layer 20 involves forming of the gas barrier layer 20 under the conditions in which the arithmetic average roughness Ra of the surface of the gas barrier layer 20 is from 0 nm to 3 nm, and the average of the diameters in the planar direction of the convexities formed on the surface is 50 nm or larger.

[Light Scattering Layer Forming Step]

First, a resin base material 11 selected from the resin film mentioned above and the like is prepared.

Next, light scattering particles 13 having an average particle size of 0.2 μm or more are dispersed in a solvent including a binder 14 such as a polysiloxane, and a resin material solution is prepared. Then, the resin material solution thus prepared is applied on the resin base material 11. The coating film is dried to thereby remove the solvent, and then a modification treatment of the binder 14 is carried out by ultraviolet irradiation. Thereby, the light scattering layer 12 is formed.

[Smoothing Layer Forming Step]

Next, a dispersion liquid in which TiO₂ nanoparticles are dispersed is mixed with a resin solution, the mixture is filtered through a filter, and thus a smoothing layer producing solution is prepared. Then, this smoothing layer producing solution is applied on the light scattering layer 12 and dried, subsequently the resultant is irradiated with ultraviolet radiation, and thus a smoothing layer 15 is formed.

[Gas Barrier Layer Forming Step]

Next, a gas barrier layer 20 is formed on the smoothing layer 15. The gas barrier layer 20 has, as illustrated in FIG. 1, a step of forming a first gas barrier layer 21 containing one or more selected from silicon nitride (SiN) and silicon oxynitride (SiON); and a step of forming a second gas barrier layer 22 containing niobium (Nb) on this first gas barrier layer 21. Alternatively, it is also acceptable to form a single layer of gas barrier layer 20 containing at least one or more selected from silicon nitride (SiN) and silicon oxynitride (SiON).

In the following description, a method for forming a first gas barrier layer 21 containing silicon nitride (SiN), a method for forming a first gas barrier layer 21 containing silicon oxynitride (SiON), and a method for forming a second gas barrier layer 22 containing niobium (Nb) will be described. In the case of forming the gas barrier layer 20 as a single layer, the gas barrier layer 20 may be formed by using a method for forming at least any one of a layer containing silicon nitride (SiN) and a layer containing silicon oxynitride (SiON).

(First Gas Barrier Layer (SiN) Forming Step: Dry Process)

As an example of the method for forming a first gas barrier layer 21 containing silicon nitride (SiN), a method for forming a layer containing silicon nitride (SiN) by a dry process using an organosilicon compound will be described. In the following description, the method for forming a first gas barrier layer 21 containing silicon nitride (SiN) using an oragnosilicon compound can also be applied to the case of forming a first gas barrier layer 21 containing a silicon oxynitride compound (SiON).

The method for forming a layer containing silicon nitride (SiN) can also be applied to a case in which the gas barrier layer 20 is configured as a single layer composed of a layer containing silicon nitride (SiN). In the case of configuring the gas barrier layer 20 as a single layer composed only of a layer containing silicon nitride (SiN), the formation of this layer containing silicon nitride (SiN) is carried out under the conditions in which the arithmetic average roughness Ra of the surface is from 0 nm to 3 nm, and the average of the diameters in the planar direction of the convexities formed on the surface is 50 nm or larger.

Also in the case of forming the first gas barrier layer 21 that serves as an undercoat of the second gas barrier layer 22, it is preferable to carry out the formation of a layer containing silicon nitride (SiN) under the conditions in which the arithmetic average roughness Ra of the surface is from 0 nm to 3 nm, and the average of the diameters in the planar direction of the convexities formed on the surface is 50 nm or larger.

In regard to the dry process, smoothness of the surface can be increased by using conditions in which the film-forming rate is relatively low. By slowing the film growth, the convexities (grain aggregates) generated on the surface can easily grow, and the diameters in the planar direction of the convexities are likely to become large. Therefore, when the film-forming rate of the first gas barrier layer 21 in a dry process is adjusted to be from 150 nm/min to 250 nm/min, the conditions that the arithmetic average roughness Ra is from 0 nm to 3 nm, and the average of the diameters in the planar direction of the convexities formed on the surface is 50 nm or larger, can be achieved.

Regarding the layer containing silicon nitride (SiN) that is included in the first gas barrier layer 21, for example, a reaction product of an inorganic silicon compound, and a reaction product of an organosilicon compound may be mentioned. Examples of the reaction product of an inorganic silicon compound include silicon oxide, silicon oxynitride, silicon nitride, silicon oxide carbide, and silicon nitride carbide.

Examples of the organosilicon compound include hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, and octamethylcyclotetrasiloxane. Among them, from the viewpoints of the handleability during the film-forming process and the characteristics such as gas barrier properties of the resulting first gas barrier layer 21, hexamethyldisiloxane and 1,1,3,3-tetramethyldisiloxane are preferred. Furthermore, these organosilicon compounds can be used singly or in combination of two or more kinds thereof.

Regarding the dry process, for example, in a case where a first gas barrier layer 21 containing silicon nitride (SiN) is formed from a reaction product of hexamethyldisiloxane, it is preferable that the molar amount (flow rate) of oxygen as a reactant gas with respect to the molar amount (flow rate) of hexamethyldisiloxane as a raw material gas is an amount equal to or less than a 12-fold amount (more preferably, equal to or less than a 10-fold amount), which is the stoichiometric ratio. When hexamethyldisiloxane and oxygen are incorporated at such a ratio, carbon atoms or hydrogen atoms in the hexamethyldisiloxane that has not been completely oxidized are incorporated into the layer, and the desired first gas barrier layer 21 can be formed. As a result, the gas barrier film 10 thus obtained can exhibit excellent gas barrier properties and bending resistance.

Furthermore, the lower limit of the molar amount (flow rate) of oxygen with respect to the molar amount (flow rate) of hexamethyldisiloxane in the film-forming gas is preferably set to an amount larger than 0.1 times the molar amount (flow rate) of hexamethyldisiloxane, and more preferably to an amount larger than 0.5 times the molar amount (flow rate) of hexamethyldisiloxane.

As a film-forming apparatus, a magnetron sputtering apparatus which includes a RF magnetron plasma generating unit and a silicon target for performing sputtering by means of the plasma thus produced, these units being connected to a vacuum treatment chamber via an inlet part, may be mentioned. The film-forming apparatus has a RF magnetron sputter source composed of a RF magnetron plasma generating unit and a target. When a plasma of argon gas is produced by the RF magnetron plasma generating unit, and RF is applied to a disc-like target, silicon atoms of the target are sputtered (RF magnetron sputter), and a film can be formed by attaching these atoms to the surface of a layer positioned downstream, or the like.

In regard to the film formation using a dry process, the chance of forming a film having components exactly according to the stoichiometric ratio is rare, due to the presence of trace amounts of gases in addition to the gas introduced. Specifically, Si₃N₄ is a representative stoichiometric value; however, there is a width in the ratio to a certain extent in an actual film, and these are inclusively considered as SiN.

The ratio of the numbers of atoms can be determined by a conventionally known method; however, for example, the ratio of the numbers of atoms can be measured with, for example, an analyzer using X-ray Photoelectron Spectroscopy (XPS), or the like.

Examples of the dry process include a vapor deposition method (resistance heating, an EB method, or the like), a plasma CVD method, a sputtering method, and an ion plating method; however, all of them can be suitably used as long as the water vapor permeability is small, and a dense film can be formed with low film stress.

(Formation of Gas Barrier Layer: Plasma CVD)

As an example of the method for forming the first gas barrier layer 21 by a dry process, a forming method using a plasma CVD method will be described. A plasma. CVD method is a method of conveying a band-shaped flexible base material while contacting the base material between a pair of film-forming rollers, and forming a film while supplying a film-forming gas in between the film-forming rollers. From the viewpoint of productivity, it is preferable that the first gas barrier layer 21 is formed by a roll-to-roll mode.

Regarding the apparatus configuration for the plasma CVD method with which the first gas barrier layer 21 can be produced, a configuration which includes a pair of film-forming rollers and a plasma power supply and is capable of performing plasma discharge between the pair of film-forming rollers, may be employed. Furthermore, it is preferable that the plasma discharge performed between the film-forming rollers is carried out such that the polarity between the film-forming rollers is alternately reversed.

An example of the production apparatus for the first gas barrier layer 21 using a plasma CVD method is illustrated in FIG. 5. The production apparatus illustrated in FIG. 5 includes a feed-out roller 51; conveying rollers 52, 53, 54, and 55; film-forming rollers 57 and 58; a gas supply port 60; a power supply for plasma generation 61; magnetic field generating apparatuses 62 and 63 provided inside the film-forming rollers 57 and 57; and a winding roller 56.

In such a production apparatus, at least film-forming rollers 57 and 58; a gas supply port 60; a power supply for plasma generation 61; and magnetic field generating apparatuses 62 and 63 formed from permanent magnet are disposed in a vacuum chamber (not shown in the diagram). Furthermore, in such a production apparatus, the vacuum chamber is connected to a vacuum pump (not shown in the diagram), and the pressure inside the vacuum chamber can be appropriately adjusted by means of such a vacuum pump.

The production apparatus is such that the film-forming roller 57 and the film-forming roller 58 are connected to the power supply for plasma generation 61. When electric power is supplied from the power supply for plasma generation 61, the film-forming roller 57 and the film-forming roller 58 are caused to function as a pair of electrodes facing each other, and plasma can be generated between the film-forming rollers 57 and 58. In regard to the production apparatus, a film having the same structure can be formed at a double film-forming rate by disposing a pair of film-forming rollers (film-forming rollers 57 and 58) such that the central axes are parallel in the same plane.

Magnetic field generating apparatuses 62 and 63 are provided inside the film-forming roller 57 and the film-forming roller 58. The magnetic field generating apparatuses 62 and 63 are provided in a fixed state so that the magnetic field generating apparatuses will not rotate even when the film-forming roller 57 and the film-forming roller 58 rotate.

Regarding the film-forming rollers 57 and 58; the feed-out roller 51; the conveying rollers 52, 53, 54, and 55; and the winding roller 56, any known rollers can be used as appropriate.

Regarding the gas supply port 60, any gas supply port capable of supplying or discharging a raw material gas or the like at a predetermined rate can be used as appropriate.

Regarding the power supply for plasma generation 61, any known power supply for a plasma generating apparatus, which can supply electric power to the film-forming roller 57 and the film-forming roller 58 connected thereto and can utilize these rollers as electrodes facing each other for discharge, can be used.

Regarding the magnetic field generating apparatuses 62 and 63, any known magnetic field generating apparatuses can be used as appropriate.

A gas barrier layer can be produced by using such a production apparatus illustrated in FIG. 5 and appropriately adjusting, for example, the type of the raw material gas, the electric power for the electrode drums of the plasma generating apparatus, the pressure inside the vacuum chamber, the diameter of the film-forming rollers, and the conveyance speed of the base material 50.

That is, by using the production apparatus illustrated in FIG. 5, plasma discharge is generated between a pair of film-forming rollers (film-forming rollers 57 and 58) while a film-forming gas (raw material gas or the like) is supplied into the vacuum chamber, thereby the film-forming gas (raw material gas or the like) is decomposed by plasma, and a gas barrier layer is formed by a plasma. CVD method on the surface of a base material 50 on the film-forming roller 57 and on the surface of a base material 50 on the film-forming roller 58.

On an occasion of forming such a film, a gas barrier layer can be formed on the surface of a base material 50 by a continuous film-forming process in the roll-to-roll mode, by respectively conveying the base material 50 using a sending roller 51, the film-forming roller 57, or the like.

In order to produce a first gas barrier layer 21 into an embodiment that satisfies all of the requirements (i) to (iv) that will be described below, the first gas barrier layer 21 can be formed by a method of changing the concentration of the film-forming gas during the film-forming process, a method of changing the position of the gas supply port 60, a method of performing gas supply at a plurality of sites, a method of providing baffle (shielding) plates in the vicinity of the gas supply port 60 and controlling the flow of the gas, a method of changing the concentration of the film-forming gas and performing plasma. CVD several times, or the like. However, a method of performing plasma CVD while putting the position of the gas supply port 60 close to any side between the film-forming roller 57 and the film-forming roller 58, is simple with good reproducibility, and is preferable.

The pressure (degree of vacuum) inside the vacuum chamber can be appropriately adjusted according to the type of the raw material gas or the like; however, it is preferable that the pressure is adjusted to be in the range of 0.5 to 100 Pa.

The conveyance speed (line speed) of the base material 50 can be appropriately adjusted according to the type of the raw material gas, the pressure inside the vacuum chamber, and the like; however, the conveyance speed is preferably adjusted to be in the range of 0.25 to 100 m/min, and more preferably in the range of 0.5 to 20 m/min.

It is preferable that the first gas barrier layer 21 formed from an organosilicon compound using a plasma. CVD method is produced into an embodiment that satisfies all of the following requirements (i) to (iv). The following requirements (i) to (iv) can be determined from the distribution curves of various constituent elements based on the elemental distribution analysis in the depth direction according to X-ray photoelectron spectroscopy (XPS depth profiling).

(i) The silicon atom ratio, the oxygen atom ratio, and the carbon atom ratio are in the following magnitude correlation of ranking in a region extending over a distance of 90% or more in the layer thickness direction from the surface of the first gas barrier layer 21:

(Carbon atom ratio)<(silicon atom ratio)<(oxygen atom ratio)

(ii) The carbon distribution curve has at least two extreme values.

(iii) The absolute value of the difference between the maximum value and the minimum value of the carbon atom ratio in the carbon distribution curve is 5 at % or higher.

(iv) In the oxygen distribution curve, the local maximum of the oxygen distribution curve that exists closest to the surface of the first gas barrier layer 21 on the base material side has the largest value among the local maxima of the oxygen distribution curve within the first gas barrier layer 21.

(Definitions of Local Maximum and Local Minimum)

An extreme value in connection with the requirements described above refers to a local maximum or a local minimum of the atomic ratio of each element with respect to the distance from the surface of the first gas barrier layer 21 in the layer thickness direction of the first gas barrier layer 21.

A local maximum is a point at which the value of the atomic ratio of an element changes from an increase to a decrease when the distance from the surface of the first gas barrier layer 21 is changed, and is a point at which the value of the atomic ratio of an element at a position that has been further changed by 20 nm in the layer thickness direction starting from the above-mentioned point, decreases by 3 at % or more.

Furthermore, a local minimum is a point at which the value of the atomic ratio of an element changes from a decrease to an increase when the distance from the surface of the first gas barrier layer 21 is changed, and is a point at which the value of the atomic ratio of an element at a position that has been further changed by 20 nm in the layer thickness direction starting from the above-mentioned point, increases by 3 at % or more.

(Relation between Average Value and Maximum Value as well as Minimum Value of Carbon Atom Ratio)

It is preferable that the carbon atom ratio in the first gas barrier layer 21 is, as an average value for the entire layer, preferably in the range of 8 at % to 20 at % from the viewpoint of flexibility, and more preferably in the range of 10 at % to 20 at %. When the carbon atom ratio is adjusted to be in that range, a first gas barrier layer 21 that sufficiently satisfies gas barrier properties and flexibility can be formed.

In regard to such a first gas barrier layer 21, it is more preferable that the absolute value of the difference between the maximum value and the minimum value of the carbon atom ratio in the carbon distribution curve is 5 at % or higher. Furthermore, it is even more preferable that the absolute value of the difference between the maximum value and the minimum value of the carbon atom ratio is 6 at % or higher, and particularly preferably 7 at % or higher. When the absolute value is 3 at % or higher, sufficient gas barrier properties are obtained in a case where the first gas barrier layer 21 thus obtainable is bent.

(Relation between Position of Extreme Value of Oxygen Atom Ratio and Maximum Value as well as Minimum Value)

From the viewpoint of preventing penetration of water molecules through the base material side, it is preferable that the local maximum of the oxygen distribution curve that exists closest to the surface of the first gas barrier layer 21 on the base material side has the maximum value among the local maxima of the oxygen distribution curve.

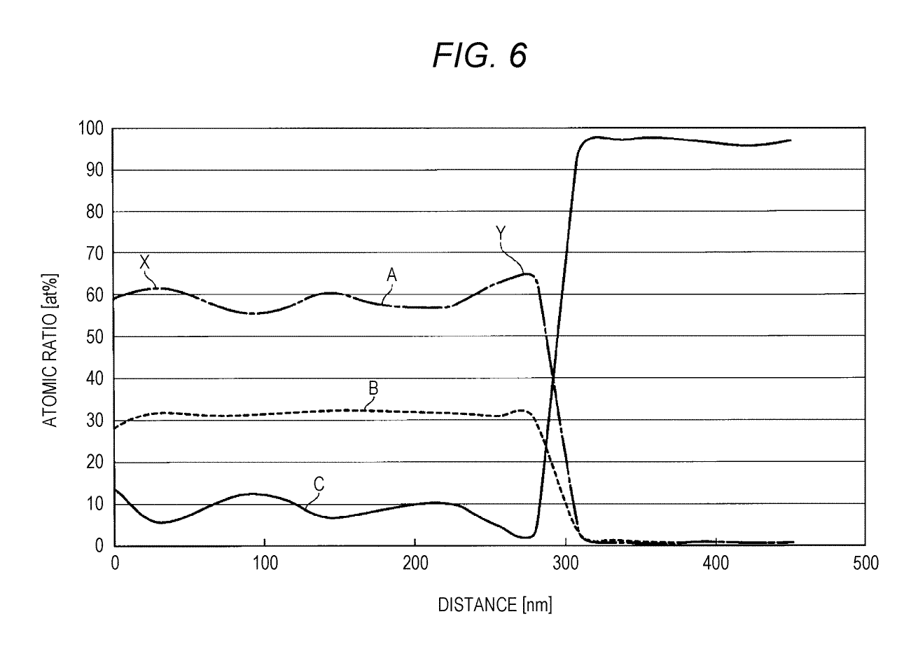

FIG. 6 is a graph showing various element profiles of the first gas barrier layer 21 in the thickness direction of the layer based on XPS depth profiling (distribution in the depth direction). In FIG. 6, the oxygen distribution curve is designated as A, the silicon distribution curve is designated as B, and the carbon distribution curve is designated as C.

As illustrated in FIG. 6, the atomic ratios of various elements continuously change from the interface between the base material and the first gas barrier layer 21 on the reverse side (distance 0 nm; hereinafter, referred to as “surface”) to the interface on the base material side (distance about 300 nm; hereinafter, referred to as “back surface”).

When the local maximum of the oxygen atom ratio that exists closest to the surface of the first gas barrier layer 21 in the oxygen distribution curve A is designated as X, and the local maximum of the oxygen atom ratio that exists closest to the back surface of the first gas barrier layer 21 is designated as Y, it is preferable that the value of the oxygen atom ratio is such that Y>X. Particularly, regarding the oxygen atom ratio, it is preferable that the oxygen atom ratio Y is 1.05 times or more the oxygen atom ratio X. That is, it is preferable that 1.05≤Y/X. Furthermore, it is preferable that the oxygen atom ratio is in the range of 1.05≤Y/X≤1.30, and even more preferably in the range of 1.05≤Y/X≤1.20. When the conditions described above are satisfied, penetration of water molecules can be suppressed, deterioration of the gas barrier properties under high-temperature and high-humidity conditions can be suppressed, and it is preferable also from the viewpoint of productivity and cost.

In regard to the oxygen distribution curve of the first gas barrier layer 21, the absolute value of the difference between the maximum value and the minimum value of the oxygen atom ratio is preferably 5 at % or higher, more preferably 6 at % or higher, and particularly preferably 7 at % or higher.

(Relation between Maximum Value and Minimum Value of Silicon Atom Ratio)

In regard to the silicon distribution curve of the first gas barrier layer 21, the absolute value of the difference between the maximum value and the minimum value of the silicon atom ratio is preferably less than 5 at %, more preferably less than 4 at %, and particularly preferably less than 3 at %. When the absolute value is in the range described above, the gas barrier properties and mechanical strength of the resulting first gas barrier layer 21 become sufficient.

(As to Compositional Analysis in Depth Direction of Gas Barrier Layer by XPS)

The distribution curves of various elements in the layer thickness (depth) direction of the first gas barrier layer 21 can be produced by so-called XPS depth profiling (distribution in the depth direction), by which exposure of the interior of a sample and a surface composition analysis are performed by using an analysis by X-ray photoelectron spectroscopy and noble gas ion sputtering in combination. A distribution curve obtainable by XPS depth profiling is produced by representing, for example, the atomic ratio (unit: at %) of each element on the vertical axis, and the etching time (sputtering time) on the horizontal axis.

Meanwhile, in the distribution curve of an element with the horizontal axis representing the etching time, the etching time roughly correlates with the distance from the surface in the layer thickness direction of the first gas barrier layer 21. Therefore, this “distance from the surface of the gas barrier layer in the layer thickness direction of the gas barrier layer” can be employed as the distance from the surface of the first gas barrier layer 21 for XPS depth profiling, the distance being calculated from the relation between the etching rate and the etching time.

Furthermore, regarding the sputtering method employed for such XPS depth profiling, a noble gas ion sputtering method that uses argon (Art) as an etching ion species is employed, and it is preferable that the etching speed (etching rate) is adjusted to be 0.05 nm/sec (value calculated relative to thermally oxidized SiO₂ film).

Furthermore, from the viewpoint of forming a uniform gas barrier layer having excellent gas barrier properties for the entire surface of the first gas barrier layer 21, it is preferable that the surface direction of the first gas barrier layer 21 (direction parallel to the surface of the first gas barrier layer 21) is substantially uniform.

When it is described that the first gas barrier layer 21 is substantially uniform in the surface direction, it is implied that in a case where an oxygen distribution curve and a carbon distribution curve are produced for any two arbitrary measurement sites at the surface of the first gas barrier layer 21 by XPS depth profiling, the numbers of extreme values possessed by the carbon distribution curve obtainable at the two arbitrary measurement sites are the same, and the absolute value of the difference between the maximum value and the minimum value of the carbon atom ratio for the respective carbon distribution curve is a difference of 5 at % or less.

Furthermore, with regard to the silicon distribution curve, the oxygen distribution curve, and the carbon distribution curve, in a case where the silicon atom ratio, the oxygen atom ratio, and the carbon atom ratio satisfy the conditions represented by condition (i) described above in a region extending over 90% or more of the layer thickness of the first gas barrier layer 21, the silicon atom ratio in the first gas barrier layer 21 is preferably in the range of 25 at % to 45 at %, and more preferably in the range of 30 at % to 40 at %.

Furthermore, the oxygen atom ratio in the first gas barrier layer 21 is preferably in the range of 33 at % to 67 at %, and more preferably in the range of 45 at % to 67 at %.

The carbon atom ratio in the first gas barrier layer 21 is preferably in the range of 3 at % to 33 at %, and more preferably in the range of 3 at % to 25 at %.

(First Gas Barrier Layer (SiON) Forming Step: Wet Process)

As an example of the method for forming the first gas barrier layer 21, a method for forming a layer containing silicon oxynitride (SiON) by a wet process using a polysilazane will be described. Meanwhile, the formation of the first gas barrier layer 21 by a wet process can also be applied to the case of using a material other than a polysilazane

The method for forming a layer containing silicon oxynitride (SiON) can also be applied to the case in which the gas barrier layer 20 is configured as a single layer composed only of a layer containing silicon oxynitride (SiON). In a case where the gas barrier layer 20 is configured as a single layer composed only of a layer containing silicon oxynitride (SiON), the formation of this layer containing silicon oxynitride (SiON) is carried out under the conditions in which the arithmetic average roughness Ra of the surface is from 0 nm to 3 nm, and the average of the diameters in the planar direction of the convexities formed on the surface is 50 nm or larger.

Also in a case where the first gas barrier layer 21 that serves as an undercoat for the second gas barrier layer 22 is formed, it is preferable that the formation of the layer containing silicon oxynitride (SiON) is carried out under the conditions in which the arithmetic average roughness Ra of the surface is from 0 nm to 3 nm, and the average of the diameters in the planar direction of the convexities formed on the surface is 50 nm or larger.

In regard to the wet process, the smoothness of the surface can be increased by using general conditions for wet processes. In regard to the wet process, the convexities (grain aggregates) generated on the surface can easily grow, and the diameters in the planar direction of the convexities are likely to become large. Therefore, in a wet process, the arithmetic average roughness Ra of the surface of the first gas barrier layer 21 can be adjusted to be from 0 nm to 3 nm, and the average of the diameters in the planar direction of the convexities formed on the surface can be adjusted to be 50 nm or larger, by applying a conventionally known technique. As such, when a wet process is applied to the formation of the first gas barrier layer 21, the conditions that the arithmetic average roughness Ra is from 0 nm to 3 nm, and the average of the diameters in the planar direction of the convexities formed on the surface is 50 nm or larger, can be achieved.

The first gas barrier layer 21 can be formed by applying and drying a coating liquid containing a polysilazane, and then irradiating the dried coating liquid with vacuum ultraviolet radiation.

Regarding the organic solvent with which the coating liquid containing a polysilazane is produced, it is preferable to avoid using a lower alcohol-based solvent or an organic solvent containing moisture, which easily reacts with a polysilazane. For example, a hydrocarbon solvent such as an aliphatic hydrocarbon, an alicyclic hydrocarbon, or an aromatic hydrocarbon; a halogenated hydrocarbon solvent; or an ether such as an aliphatic ether or an alicyclic ether can be used, and specific examples include hydrocarbons such as pentane, hexane, cyclohexane, toluene, xylene, SOLVESSO, and turben; halogen hydrocarbons such as methyelne chloride and trichloroethane; and ethers such as dibutyl ether, dioxane, and tetrahydrofuran. These organic solvents may be selected according to the purpose such as the solubility of polysilazanes or the evaporation rate of the solvent and used as mixtures with a plurality of organic solvents.

The concentration of the polysilazane in the coating liquid containing a polysilazane may vary depending on the layer thickness of the gas barrier layer or the pot life of the coating liquid; however, the concentration is preferably about 0.2% to 35% by mass.

Regarding the method for applying the coating liquid, any appropriate method is employed. Specific examples include, for example, a roll coating method, a flow coating method, an inkjet method, a spray coating method, a printing method, a dip coating method, a flow cast film-forming method, a bar coating method, and a gravure printing method.

The thickness of the coating film is appropriately set according to the purpose. For example, the thickness of the coating film is preferably in the range of 50 nm to 2 μm, more preferably in the range of 70 nm to 1.5 μm, and even more preferably in the range of 100 nm to 1 μm.

(Excimer Treatment)

In the first gas barrier layer 21, at least a portion of the polysilazane is modified into silicon oxynitride by a process of irradiating the layer containing the polysilazane with vacuum ultraviolet radiation Regarding the excimer treatment, an apparatus or method similar to that used for the light scattering layer 12 or the smoothing layer 15 can be applied.

In the vacuum ultraviolet irradiation process, the illuminance of the vacuum ultraviolet radiation at the coating film surface, which is received by the polysilazane layer coating film, is preferably in the range of 30 to 200 mW/cm², and more preferably in the range of 50 to 160 mW/cm². When the illuminance is 30 mW/cm² or greater, there is no risk of lowering of the modification efficiency, and when the illuminance is 200 mW/cm² or less, it is preferable because abrasion does not occur in the coating liquid, and the base material is not damaged.

The amount of radiated energy of vacuum ultraviolet radiation at the polysilazane layer coating film surface is preferably in the range of 200 to 10,000 mJ/cm², and more preferably in the range of 500 to 5,000 mJ/cm². When the amount of radiated energy is 200 mJ/cm² or larger, modification is sufficiently carried out, and when the amount of radiated energy is 10,000 mJ/cm² or less, excessive modification does not occur, and there is no crack generation or thermal deformation of the base material.

Regarding the light source for vacuum ultraviolet radiation, for example, a noble gas excimer lamp that emits vacuum ultraviolet radiation in the range of 100 to 230 nm is preferably used.

Oxygen is needed for the reaction at the time of irradiating with ultraviolet radiation; however, since vacuum ultraviolet radiation is absorbed by oxygen, the efficiency of the ultraviolet irradiation process may be easily decreased. Therefore, it is preferable that the irradiation with vacuum ultraviolet radiation is carried out in a state of having the oxygen concentration lowered as far as possible. That is, the oxygen concentration at the time of irradiation with vacuum ultraviolet radiation is preferably adjusted to be in the range of 10 to 10,000 ppm, more preferably in the range of 50 to 5,000 ppm, and even more preferably in the range of 1,000 to 4,500 ppm.

Regarding the gas that fills the atmosphere for irradiation, which is used at the time of irradiation with vacuum ultraviolet radiation, it is preferable to use a thy inert gas, and particularly from the viewpoint of cost, it is preferable to use dry nitrogen gas. The adjustment of the oxygen concentration can be achieved by measuring the flow rates of oxygen gas and the inert gas that are introduced into the irradiation chamber and changing the ratio of flow rates.

(Formation of Second Gas Barrier Layer: Dry Process)

As an example of the method for forming a second gas barrier layer 22 containing niobium (Nb), a method for forming a layer containing niobium oxide (NbO) by a dry process will be described.

The method for forming a second gas barrier layer 22 containing niobium (Nb) is carried out under the conditions that in the second gas barrier layer 22 containing niobium (Nb), the arithmetic average roughness Ra of the surface is from 0 nm to 3 nm, and the average of the diameters in the planar direction of the convexities formed on the surface is 50 nm or larger.

In a dry process, the smoothness of the surface can be enhanced by using conditions in which the film-forming rate is relatively low. By slowing the film growth, the convexities (grain aggregates) generated on the surface can easily grow, and the diameters in the planar direction of the convexities are likely to become large. Therefore, the conditions that the arithmetic average roughness Ra is from 0 nm to 3 nm, and the average of the diameters in the planar direction of the convexities formed on the surface is 50 nm or larger, can be achieved.

For the formation of the second gas barrier layer 22, it is preferable to use a vapor phase film-forming method from the viewpoint of the ease of adjustment of the composition ratio between elemental niobium and oxygen. The vapor phase film-forming method is not particularly limited, and examples include physical vapor deposition (PVD) methods such as a sputtering method, a vapor deposition method, and an ion plating method; and chemical vapor deposition methods such as a plasma CVD (chemical vapor deposition) method and ALD (atomic layer deposition). Among them, it is preferable to use a sputtering method since film formation is enabled without damaging the lower layers, and high productivity is obtained.

For the film-forming process according to a sputtering method, bipolar sputtering, magnetron sputtering, dual magnetron (DMS) sputtering using an intermediate frequency region, ion beam sputtering, ECR sputtering and the like can be used singly or in combination of two or more kinds thereof. Furthermore, the method of applying a target is appropriately selected according to the target species, and any of DC (direct current) sputtering and RF (radiofrequency) sputtering may be used. A reactive sputtering method utilizing a transition mode, which is intermediate between a metal mode and an oxide mode, can also be used. The reactive sputtering method is preferable because a film of a metal oxide can be formed at a high film-forming speed by controlling the sputter phenomenon so as to obtain a transition region. When DC sputtering or DMS sputtering is performed, a thin film of a metal oxide can be formed by using a metal as the target and introducing oxygen into the process gas. Furthermore, in the case of forming a film by RF (radiofrequency) sputtering, a target of a metal oxide can be used. Regarding the inert gas used for the process gas, He, Ne, Ar, Kr, Xe, and the like can be used, and it is preferable to use Ar. Furthermore, a thin film of niobium of oxide, nitride, oxynitride, oxycarbide or the like of the metal can be produced by introducing oxygen, nitrogen, carbon dioxide, or carbon monoxide into the process gas. Examples of the film-forming conditions in a sputtering method include the electric power applied, discharge current, discharge voltage, and time, and these can be appropriately selected according to the sputtering apparatus, the material of the film, film thickness, and the like. Preferably, a sputtering method of using an oxide of a metal is particularly used since the film-forming rate is higher, and higher productivity is obtained.

Since the second gas barrier layer 22 is considered as a layer having a function of suppressing oxidation of the first gas barrier layer 21 and maintaining the gas barrier properties, the gas barrier properties are not necessarily needed. Therefore, the effects of the second gas barrier layer 22 are exhibited even if the second gas barrier layer is a relatively thin layer. Specifically, in regard to the layer configuration of the first gas barrier layer 21 and the second gas barrier layer 22, the thickness of the second gas barrier layer 22 (in the case of a laminated structure of two or more layers, the total thickness) is preferably 1 to 200 nm, more preferably 2 to 100 nm, and even more preferably 3 to 50 nm, from the viewpoint of in-plane uniformity of the barrier properties. Particularly, when the thickness is 50 nm or larger, productivity of the film forming of the second gas barrier layer 22 is further enhanced.

By the process described above, a gas barrier film 10 that includes a light scattering layer 12, a smoothing layer 15, and a gas barrier layer 20, and satisfies the requirements that the surface of the gas barrier layer 20 has an arithmetic average roughness (Ra) of from 0 nm to 3 nm, and the average of the diameters in the planar direction of the convexities formed on the surface is 50 nm or larger, can be produced.

<3. Transparent Electroconductive Member>

Next, a transparent electroconductive member using the above-mentioned gas barrier film will be described. The transparent electroconductive member of the present embodiment is configured such that the gas barrier film mentioned above is provided with a transparent electroconductive layer. For the gas barrier film of the transparent electroconductive member, a configuration similar to that of the gas barrier film of the above-described embodiment can be applied. Therefore, in the following description for the transparent electroconductive member, a detailed description will not be given for a configuration similar to that of the above-mentioned gas barrier film.

[Configuration of Transparent Electroconductive Member]

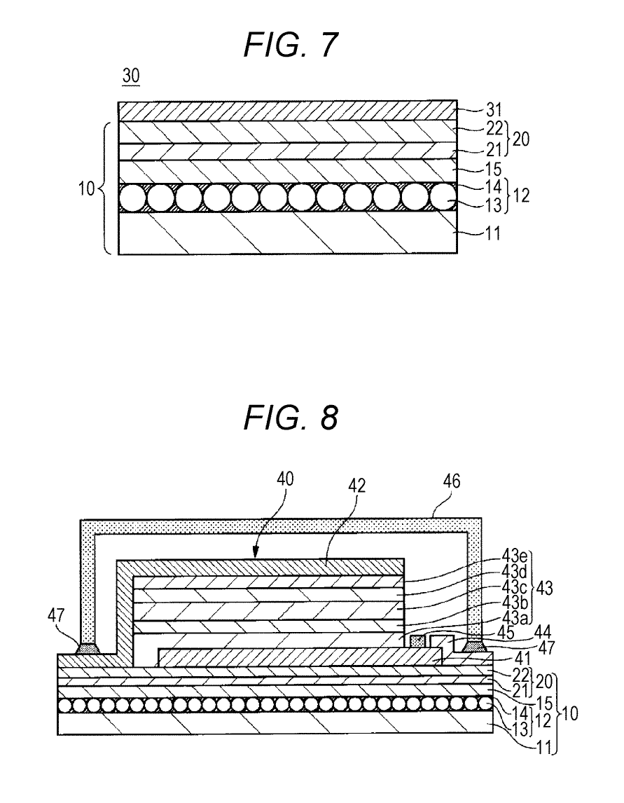

The configuration of the transparent electroconductive member of the present embodiment is presented in FIG. 7. As illustrated in FIG. 7, the transparent electroconductive member 30 is configured such that an electroconductive layer 31 is provided on the gas barrier film 10. The configuration from the resin base material 11 to the gas barrier layer 20 is a configuration similar to that of the gas barrier film 10. In regard to the gas barrier film 10, the electroconductive layer 31 is formed on the surface on the side where the gas barrier layer 20 is formed as viewed from the resin base material 11. The electroconductive layer 31 is constructed from a transparent electroconductive material. Meanwhile, being transparent means that the light transmittance at a wavelength of 550 nm is 50% or higher.

In a case where the transparent electroconductive member 30 is applied to an electronic instrument or the like, various configurations of the electronic instrument are formed on the electroconductive layer 31. Therefore, by forming the electroconductive layer 31 on the gas barrier layer 20, the adverse effects caused by moisture in the atmosphere or the like, which is transmitted by the gas barrier layer 20 through the resin base material 11, can be efficiently prevented. Furthermore, an outgas generated in the light scattering layer 12 and the smoothing layer 15 can be blocked by the gas barrier layer 20.

Furthermore, the transparent electroconductive member 30 is such that the electroconductive layer 31 is formed on the gas barrier layer 20 in which the Ra of the surface is from 0 nm to 3 nm, and the average of the diameters in the planar direction of the convexities formed on the surface of the gas barrier layer is 50 nm or less. Therefore, the undercoat that forms the electroconductive layer 31 is highly smooth, the adverse effects caused by the surface unevenness of the light scattering layer 12 are suppressed, and the reliability of an electronic instrument or the like that uses the transparent electroconductive member can be enhanced.

Therefore, as the electroconductive layer 31 is formed on a gas barrier layer 20 having a surface that satisfies the requirements described above, the adverse effects caused by moisture or outgases on the electronic instrument to which the transparent electroconductive member 30 has been applied, and the adverse effects caused by the surface unevenness attributed to the light scattering layer 12 can be suppressed. Thereby, the light extraction efficiency and reliability can be increased in the transparent electroconductive member 30 and an electronic instrument to which the transparent electroconductive member 30 has been applied.

[Electroconductive Layer]

The electroconductive layer 31 is a layer containing an electroconductive material for conducting electricity to the transparent electroconductive member 30. Examples of the electroconductive layer 31 include layers of metals such as Au, Ag, Pt, Cu, Rh, Pd, Al, and Cr; and electroconductive inorganic compounds such as In₂O₃, CdO, CdIn₂O₄, Cd₂SnO₄, TiO₂, SnO₂, ZnO, ITO (indium tin oxide), IZO (indium zinc oxide), TiN, ZrN, HfN, TiOₓ, VOₓ, CuI, InN, GaN, CuAlO₂, CuGaO₂, SrCu₂O₂, LaB₆, RuO₂, and Al. It is also acceptable to use an amorphous material from which the transparent electroconductive member 30 can be produced, such as IDIXO (In₂O₃—ZnO). An electroconductive polymer may also be used, and examples thereof include polyacetylene, poly(p-phenylenevinylene), polypyrrole, polythiophene, polyaniline, and poly(p-phenylene sulfide). In the electroconductive layer 31, these electroconductive materials may be included singly, or two or more kinds thereof may be included. Furthermore, regarding the form of the electroconductive layer, any of forms such as a uniform plane, fine lines, and a grid can be used without particular limitations.

Regarding the electroconductive layer 31, it is preferable to use a material having a high refractive index. The refractive index of silicon oxynitride that constitutes the first gas barrier layer 21 is about 1.5 to 1.7, and the refractive index of the niobium compound that constitutes the second gas barrier layer 22 is about 2. Therefore, the light extraction efficiency of the transparent electroconductive member 30 can be increased by adjusting the refractive index of the electroconductive layer 31 that is formed on the second gas barrier layer 22 of this gas barrier layer 20, to be higher than that of the niobium compound that constitutes the second gas barrier layer 22. Therefore, it is preferable to use an electroconductive material having a refractive index higher than or equal to that of the second gas barrier layer 22, as the electroconductive layer 31. As an electroconductive material having such a refractive index, it is preferable that a metal oxide having a refractive index of 2 or higher among the electroconductive materials described above is included, and for example, it is preferable that IZO, ITO, IGO, and the like are included.

Furthermore, from the viewpoint of having high electrical conductivity, it is preferable for the electroconductive layer 31 to use silver or an alloy containing silver as a main component. An alloy containing silver as a main component means that the percentage content of silver is 60 at % (atom%) or higher. Preferably, the percentage content of silver is preferably 90 at % or higher, and more preferably 95 at % or higher, from the viewpoint of electrical conductivity. Furthermore, it is preferable that the electroconductive layer 31 is constructed from simple substance of silver.

Examples of the metal that are combined with silver include zinc, gold, copper, palladium, aluminum, manganese, bismuth, neodymium, and molybdenum. For example, when silver is combined with zinc, the resistance to sulfuration of the electroconductive layer 31 increases, which is preferable. When silver is combined with gold, it is preferable because the resistance to salt (NaCl) increases. Furthermore, when silver is combined with copper, it is preferable because oxidation resistance increases.

The plasmon absorbance of the electroconductive layer 31 over the wavelength range of 400 to 800 nm (over the whole range) is preferably 10% or lower, more preferably 7% or lower, and even more preferably 5% or lower. When there is a region with a high plasmon absorbance in a portion of the wavelength range of 400 to 800 nm, the light transmitted by the transparent electroconductive member 30 is easily colored.

The plasmon absorbance at a wavelength of 400 to 800 nm of the electroconductive layer 31 is measured by the following procedures of (i) to (iii).

(i) Platinum-palladium is formed into a thickness of 0.1 nm on a glass base material using a BMC-800T vapor deposition apparatus manufactured by Shincron Co., Ltd. The average thickness of the platinum-palladium is calculated from the manufacturer's nominal value of the formation speed of the vapor deposition apparatus, or the like. Subsequently, an electroconductive layer is formed into a thickness of 20 nm by a vacuum vapor deposition method on the base material having platinum-palladium attached thereto.

(ii) Measurement light is caused to enter at an angle of inclination of 5° with respect to the normal line to the surface of the electroconductive layer thus obtained, and the transmittance and reflectance of the electroconductive layer are measured. The values of [absorbance=100−(transmittance+reflectance)] are calculated from the transmittances and reflectances at various wavelengths, and these are employed as reference data. The transmittance and reflectance are measured with a spectrophotometer.

(iii) Subsequently, an electroconductive layer of the object of measurement is formed on a similar glass base material. Then, the transmittances and reflectances are measured in the same manner for this electroconductive layer. A value calculated by subtracting the reference data from the absorbance thus obtained is designated as the plasmon absorbance of the electroconductive layer.

The thickness of the electroconductive layer 31 is preferably 10 nm or less, more preferably in the range of 3 to 9 nm, and even more preferably in the range of 5 to 8 nm. In regard to the transparent electroconductive member 30, when the thickness of the electroconductive layer 31 is adjusted to be 10 nm or less, reflection at the electroconductive layer 31 does not easily occur. Furthermore, when the thickness of the electroconductive layer 31 is 10 nm or less, the optical admittance of the transparent electroconductive member 30 can be easily adjusted, and suppression of light reflection is facilitated. The thickness of the electroconductive layer 31 can be determined by measurement using an ellipsometer.

It is preferable that the electroconductive layer 31 is composed of a fine line metal pattern, and a metal oxide layer formed so as to cover this fine line metal pattern.

In the fine line metal pattern, fine lines containing a metal are formed into a predetermined pattern having openings. On the resin base material, a part where the fine line pattern is not formed becomes an opening (translucent window part). The shape of the fine line pattern of the fine line metal pattern is not particularly limited. For example, the fine line metal pattern can be produced such that the electroconductive part is in a striped pattern, or the electroconductive part is in a lattice-like pattern or in the form of a random network. The fine line metal pattern can be formed such that, for example, the line width is 10 to 200 μm, and the height (thickness) is 0.1 to 5.0 μm.

Regarding the metal that constitutes the fine line metal pattern, the metals described for the electroconductive material mentioned above can be used. The metal that constitutes the fine line metal pattern is preferably in the form of particles or fibers (in the form of tubes, wires, or the like), and it is more preferable that the metal is in the form of nanoparticles or nanowires. Furthermore, a metal-forming material that has metal atoms (element) and produces a metal as a result of structural change such as decomposition, can also be used. Regarding the metal particles, for example, particles having an average particle size in the atomic scale to an average particle size of 1,000 nm or less can be preferably applied.

Regarding the metal oxide that covers the fine line metal pattern, the electroconductive inorganic compounds mentioned above can be used. The thickness of this metal oxide layer can be adjusted to be in the range of 10 to 500 nm.

(Undercoat Layer)

Between the gas barrier film 10 and the electroconductive layer 31, there may be a layer having a composition different from these layers. For example, an undercoat layer for forming the electroconductive layer 31 may be provided.

In a case where the above-mentioned metal, for example, silver or an alloy containing silver as a main component is used in the electroconductive layer 31 of the transparent electroconductive member 30, if necessary, it is preferable to form an undercoat layer that serves as a growth nucleus at the time of forming the electroconductive layer 31, or an undercoat layer formed from an organic compound containing a nitrogen atom, which is applied to an electron transporting material that will be described below. The undercoat layer is a layer formed on the side of the gas barrier film 10 rather than the electroconductive layer 31, adjacently to the electroconductive layer 31, and it is preferable that the electroconductive layer 31 is formed directly on this undercoat layer.

When the transparent electroconductive member 30 has an undercoat layer, even in a case where the thickness of the electroconductive layer 31 is small, smoothness of the surface of the electroconductive layer 31 increases. When the material of the electroconductive layer 31 is vapor deposited on the gas barrier layer 20 by a general vacuum vapor deposition method, in the early stage of formation, the atoms attached by vapor deposition migrate (move), and the atoms form aggregates (sea-island structure). Then, the film grows while the atoms cling to these aggregates. Therefore, in the film of the early stage of formation, there are gaps between the aggregates, and conduction does not occur. When the aggregates further grow from this state, some of the aggregates are connected, and conduction barely occurs. However, since there still are gaps between the aggregates, plasmon absorption occurs. Then, when the formation further occurs, the aggregates are completely connected, and plasmon absorption is reduced. However, on the other hand, reflection intrinsic to the metal occurs, and light transmissibility of the film is decreased.

In contrast, when the material of the electroconductive layer 31 is vapor deposited on the undercoat layer formed from a metal that does not migrate easily, the electroconductive layer 31 grows by taking the undercoat layer as the growth nucleus. That is, the material of the electroconductive layer 31 does not migrate easily, and the film grows without forming the sea-island structure described above. As a result, an electroconductive layer 31 that is smooth even if the thickness is small is likely to be obtained.

It is preferable that an organic compound containing a nitrogen atom; palladium, molybdenum, zinc, germanium, niobium, or indium; any of alloys of these metals with other metals; or any of oxides or sulfides of these metals (for example, ZnS) is included in the undercoat layer. The undercoat layer may include only one kind of these, or may include two or more kinds thereof. Particularly, it is preferable that the undercoat layer includes palladium or molybdenum.

The amount of the metal included in the undercoat layer is preferably 20% by mass or more, more preferably 40% by mass or more, and even more preferably 60% by mass or more. When an organic compound containing a nitrogen atom, or the above-mentioned metal is included in the undercoat layer in an amount of 20% by mass or more, the affinity between the undercoat layer and the electroconductive layer 31 increases, and the adhesiveness between the undercoat layer and the electroconductive layer 31 is likely to increase. Furthermore, the metals that form alloys with palladium, molybdenum, zinc, germanium, niobium, or indium are not particularly limited; however, for example, platinum group metals other than palladium, gold, cobalt, nickel, titanium, aluminum, and chromium can be used.

In a case where the undercoat layer includes the metal described above, the thickness of the undercoat layer is preferably 3 nm or less, more preferably 0.5 nm or less, and particularly preferably a monoatomic film. The undercoat layer may be in a state in which metal atoms are attached to the surface of formation separately apart from each other. When the amount of attachment of the undercoat layer is 3 nm or less, the undercoat layer does not easily affect the light transmissibility or optical admittance of the transparent electroconductive member 30. The presence or absence of the undercoat layer is checked by an ICP-MS method.

In a case where the undercoat layer includes an organic compound containing a nitrogen atom, the thickness of the undercoat layer is preferably 10 to 100 nm.

The thickness of the undercoat layer is calculated from the product of the formation speed and the formation time.

<4. Method for Producing Transparent Electroconductive Member>

Next, the method for producing a transparent electroconductive member will be described. The method for producing a transparent electroconductive member includes a step of forming an electroconductive layer on a gas barrier layer, after the various steps for producing a gas barrier film described above. Regarding the production process for the gas barrier film, a process similar to the method for producing a gas barrier film as described above can be applied. Therefore, in the following description, only the step of forming an electroconductive layer on a gas barrier film will be described.

[Electroconductive Layer Forming Step]

In the production process for the gas barrier film 10 described above, a gas barrier layer 20 that satisfies the requirements that the arithmetic average roughness (Ra) of the surface is from 0 nm to 3 nm, and the average of the diameters in the planar direction of the convexities formed on the surface is 50 nm or larger is formed, and then an undercoat layer formed from, for example, a compound containing a nitrogen atom is formed on this gas barrier layer 20 by an appropriate method such as a vapor deposition method, such that the thickness is 1 μm or less, and preferably in the range of 10 to 100 nm.

It is preferable that the undercoat layer is formed by a vapor deposition method or a sputtering method. Examples of the vapor deposition method include a vacuum vapor deposition method, an electron beam vapor deposition method, an ion plating method, and an ion beam vapor deposition method. The vapor deposition time is appropriately selected according to the desired thickness of the undercoat layer and the formation speed. The vapor deposition rate is preferably 0.01 to 1.5 nm/sec, and more preferably 0.01 to 0.7 nm/sec.

Next, an electroconductive layer 31 formed from silver or an alloy containing silver as a main component is formed on the undercoat layer by an appropriate method such as a vapor deposition method, so as to obtain a layer thickness of 12 nm or less, and preferably 4 to 9 nm.

The electroconductive layer 31 may be formed by any method; however, it is preferable that the electroconductive layer 31 is formed by a vacuum vapor deposition method or a sputtering method. When a vacuum vapor deposition method or a sputtering method is used, there is no chance of exposing the resin base material 11 to a high-temperature environment, and an electroconductive layer 31 having high flatness can be formed very rapidly.

Examples of the vapor deposition method that is applicable include a resistance heating vapor deposition method, an electron beam vapor deposition method, an ion plating method, and an ion beam vapor deposition method. Regarding the vapor deposition apparatus, for example, a BMC-800T vapor depositing machine manufactured by Shincron Co., Ltd., or the like can be used.

Regarding the sputtering method, known sputtering methods such as a bipolar sputtering method, a magnetron sputtering method, a DC sputtering method, a DC pulse sputtering method, an RF (radiofrequency) sputtering method, a dual magnetron sputtering method, a reactive sputtering method, an ion beam sputtering method, a bias sputtering method, and a counter target sputtering method can be adequately used. Specific examples of commercially available sputtering apparatuses that can be used include a magnetron sputtering apparatus manufactured by Osaka Vacuum, Ltd., various sputtering apparatuses of Ulvac Technologies, Inc. (for example, a multi-chamber type sputtering apparatus, ENTRON (trademark) -EX W300), and L-4305-FHS sputtering apparatus of Canon Anelva Corp.

When a vacuum vapor deposition method or a sputtering method is used, an electroconductive layer 31 having high flatness can be formed at a very fast formation speed. Furthermore, when the electroconductive layer 31 is formed on the gas barrier layer 20, the formation speed for the electroconductive layer 31 containing silver as a main component is preferably 0.3 nm/sec or higher. The formation speed for the electroconductive layer 31 is more preferably in the range of 0.5 to 30 nm/sec, and particularly preferably in the range of 1.0 to 15 nm/sec. Furthermore, the temperature employed at the time of film forming is preferably in the range of −25° C. to 25° C. The reached degree of vacuum before the initiation of film forming is preferably 3×10⁻³ Pa or less, and more preferably 7×10⁻⁴ Pa or less.

Meanwhile, when the electroconductive layer 31 is formed on an undercoat layer, the undercoat layer serves as a growth nucleus at the time of forming the electroconductive layer 31, and therefore, the electroconductive layer 31 is likely to become a smooth film. As a result, even if the electroconductive layer 31 is thin, plasmon absorption does not easily occur.

By the processes described above, a transparent electroconductive member 30 in which an electroconductive layer 31 is formed on a gas barrier film 10 can be produced. In the production of this transparent electroconductive member 30, a transparent electroconductive layer 31 is formed on a gas barrier film 10 produced by the production method described above. Therefore, the gas barrier layer 20 of the gas barrier film 10 satisfies the requirements that the arithmetic average roughness (Ra) is from 0 nm to 3 nm, and the average of the diameters in the planar direction of the convexities formed on the surface is 50 nm or larger.

Therefore, also in regard to the transparent electroconductive member 30 produced by the production method described above, the reliability of an electronic instrument or the like that uses the transparent electroconductive member can be increased by increasing the smoothness of the undercoat of the electroconductive layer 31.

<5. Organic Electroluminescence Element>

Next, an embodiment of an organic electroluminescence element (organic EL element) that uses the gas barrier film described above will be described. The organic EL element of the present embodiment is configured such that electrodes (positive electrode and negative electrode) and a light emitting unit are provided on the gas barrier film mentioned above. Furthermore, an organic EL element can be configured using the transparent electroconductive member described above as a gas barrier film for an organic EL element, and as an electrode. Therefore, in the following description of the organic EL element, the detailed description will not be repeated here with regard to the same configuration as the gas barrier film and the transparent electroconductive member described above.

[Configuration of Organic EL Element]

The configuration of the organic EL element of the present embodiment is illustrated in FIG. 8. The organic EL element 40 illustrated in FIG. 8 includes a gas barrier film 10, a pair of electrodes composed of a first electrode 41 and a second electrode 42, and a light emitting unit 43 provided between the electrodes. The gas barrier film 10 has a configuration similar to that of FIG. 1 mentioned above.

Here, the “light emitting unit” refers to a luminescent body (unit) configured to include, as main bodies, at least organic functional layers such as a light emitting layer 43c, a hole transport layer 43b, and an electron transport layer 43d, all of which contain various organic compounds. A luminescent body is interposed between a pair of electrodes composed of a positive electrode and a negative electrode, and emits light as the holes supplied from the positive electrode and the electrons supplied from the negative electrode recombine in that luminescent body. Meanwhile, an organic EL element may include a plurality of the light emitting units according to desired luminescent colors.

Only the part in which the light emitting unit 43 is sandwiched between the first electrode 41 and the second electrode 42 becomes a light emitting region in the organic EL element 40. The organic EL element 40 is configured as a bottom emission type, in which generated light (hereinafter, described as emitted light h) is extracted through at least the resin base material 11 side. Meanwhile, transparency (translucency) means that the light transmittance at a wavelength of 550 nm is 50% or higher. A main component is a component that occupies the highest proportion in the entire composition.

At a terminal of the first electrode 41, an extraction electrode 44 is provided. The first electrode 41 is electrically connected to an external power supply (not shown in the diagram) through the extraction electrode 44. Furthermore, it is also acceptable that an auxiliary electrode 45 is provided adjacently to the first electrode 41 for the purpose of promoting resistance decrease in the first electrode 41.

The layer structure of the organic EL element 40 is not limited and may be any general layer structure. For example, in a case where the first electrode 41 functions as an anode (that is, a positive electrode), and the second electrode 42 functions as a cathode (that is, a negative electrode), a configuration in which hole injection layer 43a/hole transport layer 43b/light emitting layer 43c/electron transport layer 43d/electron injection layer 43e are laminated in order from the first electrode 41 side is taken as an example for the light emitting unit 43; however, it is essential that the light emitting unit 43 has at least a light emitting layer 43c constructed using an organic material in this configuration. The hole injection layer 43a and the hole transport layer 43b may be provided as a hole transport-injection layer. The electron transport layer 43d and the electron injection layer 43e may be provided as an electron transport-injection layer. Furthermore, within this light emitting unit 43, for example, the electron injection layer 43e may be constructed from an inorganic material.

In the light emitting unit 43, a hole blocking layer, an electron blocking layer or the like may be laminated at a necessary site, if necessary, in addition to these layers. Furthermore, the light emitting layer 43c may include various colored light emitting layers that generate emitted light in various wavelength regions and may have a structure in which these various colored light emitting layers are laminated, with non-luminescent auxiliary layers being interposed therebetween. The auxiliary layers may also function as hole blocking layers or electron blocking layers. Furthermore, the second electrode 42, which is a cathode, may also have a laminated structure according to necessity. In such a configuration, only the part in which the light emitting unit 43 is sandwiched between the first electrode 41 and the second electrode 42 becomes a light emitting region in the organic EL element 40.

An organic EL element 40 having such a configuration as described above is encapsulated by an encapsulating member 46 that will be described below, for the purpose of preventing deterioration of the light emitting unit 43 constructed using an organic material or the like. This encapsulating member 46 is fixed to the side of the gas barrier film 10 by means of an adhesive portion 47. However, the terminal portions of the first electrode 41 (extraction electrode 44) and the second electrode 42 are exposed from the encapsulating member 46 in a state of maintaining insulativeness from each other.

Furthermore, the organic EL element 40 may be an element having a so-called tandem structure, in which a plurality of light emitting units 43 each including at least one layer of light emitting layer are laminated. Regarding a representative element configuration of the tandem structure, for example, the following configuration may be mentioned.

Positive electrode/first light emitting unit/intermediate connector layer/second light emitting unit/intermediate connector layer/third light emitting unit/negative electrode

Here, the first light emitting unit, the second light emitting unit, and the third light emitting unit may all be identical or different. It is also acceptable that two light emitting units are identical, while the remaining one is different.

A plurality of the light emitting units 43 may be laminated directly or may be laminated with intermediate connector layers interposed therebetween.

An intermediate connector layer is generally referred to as intermediate electrode, intermediate electroconductive layer, charge generating layer, electron withdrawing layer, connecting layer, or intermediate insulating layer, and as long as the intermediate connector layer is a layer having a function of supplying electrons to a layer adjacent to the positive electrode side and holes to a layer adjacent to the negative electrode side, any known material configuration can be used. Examples of the material used for the intermediate connector layer include ITO (indium tin oxide), IZO (indium zinc oxide); electroconductive inorganic compound layers of ZnO₂, TiN, ZrN, HfN, TiOₓ, VOₓ, CuI, InN, GaN, CuAlO₂, CuGaO₂, SrCu₂O₂, LaB₆, RuO₂, and Al; bilayer films of Au/Bi₂O₃; multilayer films of SnO₂/Ag/SnO₂, ZnO/Ag/ZnO, Bi₂O₃/Au/Bi₂O₃, TiO₂/TiN/TiO₂, and TiO₂/ZrN/TiO₂; electroconductive organic substance layers of fullerene such as C60, and an oligothiophene; and electroconductive organic compound layers of metal phthalocyanines, non-metal phthalocyanines, metal porphyrins, and non-metal porphyrins; however, the examples are not limited to these.

A preferred configuration of the light emitting unit 43 may be, for example, a configuration obtainable by excluding a positive electrode and a negative electrode from the configuration mentioned above as the representative element configuration; however, the preferred configuration is not limited to this.

Specific examples of the tandem type organic EL element include the element configurations and constituent materials described in, for example, U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087 A, JP 2006-228712 A, JP 2006-24791 A, JP 2006-49393 A, JP 2006-49394 A, JP 2006-49396 A, JP 2011-96679 A, JP 2005-340187 A, JP 4711424 B2, JP 3496681 B2, JP 3884564 B2, JP 4213169 B2, JP 2010-192719 A, JP 2009-076929 A, JP 2008-078414 A, JP 2007-059848 A, JP 2003-272860 A, JP 2003-045676 A, and WO 2005/094130 A.

Hereinafter, important constituent elements and method for producing the same in connection with the organic EL element will be described.

[Electrodes]

The organic EL element 40 has a light emitting unit 43 sandwiched between a pair of electrodes composed of a first electrode 41 and a second electrode 42. Regarding the first electrode 41 and the second electrode 42, any one of them becomes a positive electrode for the organic EL element 40, and the other becomes a negative electrode.

In the organic EL element 40 illustrated in FIG. 8, the first electrode 41 is constructed from a transparent electroconductive material, and the second electrode 42 is constructed from a highly reflective material. In a case where the organic EL element 40 is a both-sided light emission type, the first electrode 41 and the second electrode 42 are both constructed from a transparent electrode material. Regarding the transparent electroconductive material for the first electrode 41 and the second electrode 42, the configuration of the electroconductive layer of the transparent electroconductive member of the embodiment described above can be applied. Furthermore, a configuration in which an undercoat layer is provided in accordance with this electroconductive layer can also be employed.

[Positive Electrode and Negative Electrode]

Regarding the positive electrode for the organic EL element 40, an electrode produced from any of a metal having a large work function (4 eV or higher), an alloy, an electrically conductive compound, and a mixture thereof as the electrode material, is preferably used. Specific examples of the electrode material that can constitute a positive electrode include metals such as Au and Ag; and electroconductive transparent materials such as CuI, indium tin oxide (ITO), SnO₂, and ZnO. Furthermore, an amorphous material with which a transparent electroconductive film can be produced, such as IDIXO (In₂O₃—ZnO) may also be used.

Regarding the positive electrode, one of electrode materials may be formed into a thin film by a method such as vapor deposition or sputtering, and a pattern having a desired shape may be formed by a photolithography method, or when high pattern accuracy is not needed (about 100 μm or larger), a pattern may be formed by means of a mask having a desired shape at the time of vapor deposition or sputtering of the electrode material.

In the case of using a substance that can be applied, such as an organic electroconductive compound, a wet film forming method such as a printing system or a coating system can also be used. When emitted light is extracted through the positive electrode side, it is desirable that the transmittance is adjusted to be higher than 10%. Furthermore, the sheet resistance as the positive electrode is preferably several hundred Ω/sq. or less. The film thickness may vary depending on the material; however, the film thickness is usually selected to be in the range of 10 to 1,000 nm, and preferably in the range of 10 to 200 nm.

A negative electrode is an electrode film that functions as a negative electrode (cathode) supplying electrons to the light emitting unit 43. Regarding the negative electrode, an electrode formed from any of a metal having a small work function (4 eV or less) (referred to as electron-injecting metal), an alloy, an electrically conductive compound, and a mixture thereof as the electrode material, is used.

Specific examples of such an electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and rare earth metals.

Among these, from the viewpoints of electron injectability and durability against oxidation or the like, a mixture of an electron-injecting metal and a second metal, which is a stable metal having a larger value of work function than the electron-injecting metal, for example, a magnesium/silver mixture, a magnesium/aluminum mixture, a magnesium/indium mixture, an aluminum/aluminum oxide (Al₂O₃) mixture, a lithium/aluminum mixture, or aluminum, is suitable.

The negative electrode can be produced by forming a thin film of one of these electrode materials by a method such as vapor deposition or sputtering.

The sheet resistance as a negative electrode is preferably several hundred Ω/sq. or less, and the film thickness is usually selected in the range of 10 nm to 5 μm, and preferably in the range of 50 to 200 nm. Furthermore, a transparent or semi-transparent negative electrode can be produced by producing the metal into a negative electrode having a film thickness of 1 to 20 nm, and then producing thereon an electroconductive transparent material mentioned in the description for the positive electrode. When this is applied, an element in which both the positive electrode and the negative electrode have transmissibility can be produced.

[Auxiliary Electrode]

An auxiliary electrode 45 is provided for the purpose of decreasing the resistance of the first electrode 41, and it is preferable that the auxiliary electrode is provided adjacently to the first electrode 41.

As the material that forms the auxiliary electrode 45, a metal having low resistance, such as gold, platinum, silver, copper, or aluminum is preferred. Since these metals have low light transmissibility, a pattern is formed to the extent that there is no influence on the extraction of emitted light h through the light extraction surface.

The line width of the auxiliary electrode 45 is preferably 50 μm or less from the viewpoint of the aperture ratio of light extraction, and the thickness of the auxiliary electrode 45 is preferably 1 μm or more from the viewpoint of electrical conductivity.

Examples of the method for forming such an auxiliary electrode 45 include a vapor deposition method, a sputtering method, a printing method, an inkjet method, and an aerosol jetting method.

[Extraction Electrode]

An extraction electrode 44 electrically connects the first electrode 41 and an external power supply, and any known material can be suitably used without any particular limitations on the material of the electrode. However, for example, a metal film such as a MAM electrode (Mo/Al—Nd alloy/Mo) having a three-layer structure can be used.

[Light Emitting Layer]

A light emitting layer 43c is a layer that emits light as a result of recombination of electrons injected from an electrode or an electron transport layer 43d and holes injected from a hole transport layer 43b, and the light emitting portion may be within the layer of the light emitting layer 43c or may be an interface between the light emitting layer 43c and an adjacent layer.

Regarding such a light emitting layer 43c, there are no particular limitations on the configuration of the layer as long as the luminescent material included therein satisfies the requirement of light emission. It is also acceptable that a plurality of layers having the same light emission spectrum or the same maximum emission wavelength. In this case, it is preferable that non-luminescent auxiliary layers (not shown in the diagram) are provided between the various light emitting layers 43c.

The sum total of the layer thicknesses of the light emitting layers 43c is preferably in the range of 1 to 100 nm, and from the viewpoint that a lower driving voltage can be obtained, the sum total of the layer thicknesses is more preferably in the range of 1 to 30 nm. Regarding the sum total of the layer thicknesses of the light emitting layers 43c, in a case where non-luminescent intermediate layers exist between the light emitting layers 43c, the sum total is the layer thickness that also includes these intermediate layers.

In the case of a light emitting layer 43c having a configuration in which a plurality of layers are laminated, the layer thickness of individual light emitting layers is preferably adjusted in the range of 1 to 50 nm, and more preferably adjusted in the range of 1 to 20 nm. When a plurality of light emitting layers thus laminated corresponds respectively to the luminescent colors of blue, green and red, there are no particular limitations on the relation between the layer thicknesses of the various light emitting layers of blue, green, and red.

Regarding the configuration of the light emitting layer 43c, it is preferable that the light emitting layer 43c includes a host compound (luminescent compound or the like) and a luminescent material (luminescent dopant), and light is emitted by the luminescent material. For the light emitting layer 43c, a plurality of luminescent materials may be mixed, and for example, a phosphorescent light emitting compound (phosphorescent compound, phosphorescent light emitting material) and a fluorescent light emitting material (fluorescent dopant, fluorescent compound) may be used as a mixture in the same light emitting layer 43c. It is preferable that the light emitting layer 43c includes a phosphorescent light emitting compound as a luminescent material. The light emitting layer 43c can be formed by forming a film of the luminescent material or host compound that will be described below, by a known thin film forming method such as, for example, a vacuum vapor deposition method, a spin coating method, a casting method, an LB method, or an inkjet method.

(1) Host Compound

Regarding a host compound that is included in the light emitting layer 43c, a compound having a phosphorescence quantum yield of phosphorescent light emission of less than 0.1 at room temperature (25° C.) is preferred. More preferably, the phosphorescence quantum yield is less than 0.01. Among the compounds included in the light emitting layer 43c, a compound whose volume ratio in the layer is 50% or higher is preferred.

Regarding the host compound, a known host compound may be used alone, or a plurality of kinds may be used. When a plurality of kinds of host compounds is used, migration of charge can be adjusted, and the efficiency of the organic EL element can be increased. Furthermore, different emitted lights can be mixed by using a plurality of kinds of the luminescent materials that will be described below, and thereby any arbitrary luminescent colors can be obtained.

The host compound may be a conventionally known low molecular weight compound or a polymer compound having a repeating unit, and may also be a low molecular weight compound having a polymerizable group such as a vinyl group or an epoxy group (vapor deposition polymerizable luminescent host).

Regarding a known host compound, a compound which has hole transporting ability or electron transporting ability, prevents wavelength increase of the emitted light, and has a high Tg (glass transition temperature) is preferred.

The glass transition point (Tg) as used herein is a value that can be determined by a method equivalent to JIS K 7121 by using DSC (Differential Scanning Calorimetry).

Regarding specific examples of known host compounds, the compounds described in the following documents can be used. For example, JP 2010-251675 A, JP 2001-257076 A, JP 2002-308855 A, JP 2001-313179A, JP 2002-319491 A, JP 2001-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645 A, JP 2002-338579 A, JP 2002-105445 A, JP 2002-343568 A, JP 2002-141173 A, JP 2002-352957 A, JP 2002-203683 A, JP 2002-363227 A, JP 2002-231453 A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, and JP 2002-308837 A.

(2) Luminescent Material

Examples of the luminescent material include a phosphorescent light emitting compound (phosphorescent compound, phosphorescent light emitting material) and a fluorescent light emitting compound (fluorescent compound, fluorescent light emitting material).

(Phosphorescent Light Emitting Compound)

A phosphorescent light emitting compound is a compound in which light emission from excited triplets is observed. Specifically, the phosphorescent light emitting compound is defined as a compound that emits phosphorescent light at room temperature (25° C.), and as a compound having a phosphorescence quantum yield at 25° C. of 0.01 or higher. A preferred phosphorescence quantum yield is 0.1 or higher.

The phosphorescence quantum yield can be measured by the method described in Jikken Kagaku Koza 7(Experimental Chemistry Lecture Series 7), 4^{th} Edition, Spectroscopy II, p. 398 (1992, Maruzen Co., Ltd.). The phosphorescence quantum yield in a solution can be measured using various solvents; however, in the case of using a phosphorescent light emitting compound, it is desirable that the above-mentioned phosphorescence quantum yield (0.01 or higher) is achieved in any of arbitrary solvents.

Regarding the principle of light emission of a phosphorescent light emitting compound, two kinds of principles may be considered.

One of them is energy transfer type light emission, in which recombination of carriers occurs on a host compound to which carriers are transported, an excited state of the host compound is produced, this energy is transferred to a phosphorescent light emitting compound, and thereby light emission from the phosphorescent light emitting compound is obtained.

The other is carrier trap type light emission, in which a phosphorescent light emitting compound becomes a carrier trap, recombination of carriers occurs on the phosphorescent light emitting compound, and thus light emission from the phosphorescent light emitting compound is obtained.

In both cases, the conditions in which the energy in an excited state of the phosphorescent light emitting compound is lower than the energy in an excited state of the host compound are established.

The phosphorescent light emitting compound can be appropriately selected from those used in a light emitting layer of a general organic EL element and used. Preferably, the phosphorescent light emitting compound is a complex-based compound containing a metal of Group 8 to Group 10 of the Periodic Table of Elements, and more preferably, the phosphorescent light emitting compound is an iridium compound, an osmium compound, a platinum compound (platinum complex based compound), or a rare earth metal complex. Particularly preferred is an iridium compound.

Specific examples of the phosphorescent light emitting compound that can be used include the compounds described in JP 2010-251675 A; however, the examples are not limited to these.

The amount of the phosphorescent light emitting compound is preferably 0.1% by volume or more and less than 30% by volume with respect to the total amount of the light emitting layer 43c. The light emitting layer 43c may include two or more kinds of phosphorescent light emitting compounds, and the concentration ratio of the phosphorescent light emitting compounds in the light emitting layer 43c may change along the thickness direction of the light emitting layer 43c.

(Fluorescent Light Emitting Compound)

Examples of a fluorescent light emitting compound include a coumarin-based dye, a pyran-based dye, a cyanine-based dye, a chroconium-based dye, a squarylium-based dye, an oxobenzanthracene-based dye, a fluorescein-based dye, a rhodamine-based dye, a pyrylium-based dye, a perylene-based dye, a stilbene-based dye, a polythiophene-based dye, and a rare earth metal complex-based fluorophore.

[Injection Layers: Hole Injection Layer and Electron Injection Layer]

An injection layer is a layer provided between the electrodes and the light emitting layer 43c for the purpose of decreasing the driving voltage or increasing the light emission luminance, and the details are described in “Yuki EL Soshi to Sono Kogyoka Saizensen (Organic EL Elements and Forefront of Industrialization Thereof) (Nov. 30, 1998, published by NTS Publishing, Ltd.)”, Vol. 2, Chapter 2 “Electrode Materials” (pp. 123 to 166). Injection layers include hole injection layer 43a and electron injection layer 43e.

An injection layer can be provided as necessary. In the case of a hole injection layer 43a, the hole injection layer may be provided between the positive electrode and the light emitting layer 43c or the hole transport layer 43b, and in the case of an electron injection layer 43e, the electron injection layer may be provided between the negative electrode and the light emitting layer 43c or the electron transport layer 43d.

Regarding the hole injection layer 43a, the details are described in JP 9-45479 A, JP 9-260062 A, JP 8-288069 A, and the like, and specific examples include a polymer layer using an electroconductive polymer such as a phthalocyanine layer represented by copper phthalocyanine; an oxide layer represented by vanadium oxide; an amorphous carbon layer; and a polymer layer using an electroconductive polymer such as polyaniline (emeraldine) or polythiophene.

In regard to the electron injection layer 43e, the details are described in JP 6-325871 A, JP 9-17574 A, JP 10-74586 A, and the like, and specific examples include a metal layer represented by strontium or aluminum; an alkali metal halide layer represented by potassium fluoride; an alkaline earth metal compound layer represented by magnesium fluoride; and an oxide layer represented by molybdenum oxide. It is desirable that the electron injection layer 43e is a layer formed from a very thin film, and while the layer thickness of the electron injection layer may vary depending on the material, the layer thickness is preferably in the range of 1 nm to 10 μm.

[Hole Transport Layer]

The hole transport layer 43b is formed from a hole transporting material having a function of transporting holes, and in a wide sense, the hole injection layer 43a and the electron blocking layer are also included in the hole transport layer 43b.

The hole transport layer 43b cab be provided as a single layer or a plurality of layers. The hole transport layer 43b may have a single-layer structure formed from one kind or two or more kinds of the materials described below.

The hole transporting material has any of injection or transport of holes and barrier performance against electron, and may be any of an organic substance and an inorganic substance. Examples include a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, an electroconductive polymer oligomer, and particularly a thiophene oligomer. Particularly, it is preferable to use a porphyrin compound, an aromatic tertiary amine compound, and a styrylamine compound, and particularly to use an aromatic tertiary amine compound.

Representative examples of the aromatic tertiary amine compound and the styrylamine compound include N,N,N′,N′-tetraphenyl-4,4′-diaminophenyl, N,N′-diphenyl-N,N′-bis(3-methylphenyl)-[1,1′-biphenyl]-4,4′-diamine (TPD), 2,2-bis(4-di-p-tolylaminophenyl)propane, 1,1-bis(4-di-p-tolylaminophenyl)cyclohexane, N,N,N′,N′-tetra-p-tolyl-4,4′-diaminobiphenyl, 1,1-bis(4-di-p-tolylaminophenyl)-4-phenylcyclohexane, bis(4-dimethylamino-2-methylphenyl)phenylmethane, bis(4-di-p-tolylaminophenyl)phenylmethane, N,N′-diphenyl-N,N′-di(4-methoxyphenyl)-4,4′-diaminobiphenyl, N,N,N′,N′-tetraphenyl-4,4′-diaminiodiphenyl ether, 4,4′-bis(diphenylamino)quadriphenyl, N,N,N-tri(p-tolyl)amine, 4-(di-p-tolylamino)-4′-[4-(di-p-tolylamino)styryl]stilbene, 4-N,N-diphenylamino-(2-diphenylviny)benzene, 3-methoxy-4′-N,N-diphenylaminostilbenzene, N-phenylcathazole, and compounds having two fused aromatic rings in the molecule as described in U.S. Pat. No. 5,061,569, for example, 4,4′-bis[N-(1-naphthyl)-N-phenylamino]biphenyl (NPD), and 4,4′,4″-tris[N-(3-methylphenyl)-N-phenylamino]triphenylamine (MTDATA), in which three triphenylamine units are connected into a star-burst form as described in JP 4-308688 A.

Furthermore, polymer materials in which these materials have been introduced into the polymer chain, or polymer materials in which these materials are used as the main chains of the polymer can also be used. Furthermore, inorganic compounds such as p-type Si and p-type SiC can also be used as hole injection materials and hole transporting materials. Furthermore, so-called p-type hole transporting materials described in JP 11-251067 A and J. Huang et al., Applied Physics Letters, 80(2002), p. 139 can also be used. It is preferable to use these materials because luminescent elements with higher efficiency can be obtained.

The p-properties can be enhanced by doping impurities into the material for the hole transport layer 43b. For example, the materials described in JP 4-297076 A, JP 2000-196140 A, JP 2001-102175 A, and J. Appl. Phys., 95, 5773 (2004) may be mentioned. When the p-properties of the hole transport layer 43b are enhanced, an element of lower power consumption can be produced.

There are no particular limitations on the layer thickness of the hole transport layer 43b; however, the layer thickness is usually about 5 nm to 5 μm, and preferably in the range of 5 to 200 nm.

The hole transport layer 43b can be formed by producing a thin film of any of the hole transport materials described above by a known method such as, for example, a vacuum vapor deposition method, a spin coating method, a casting method, a printing method including an inkjet method, or an LB method.

[Electron Transport Layer]

The electron transport layer 43d is formed from a material having a function of transporting electrons, and in a wide sense, the electron injection layer 43e and the hole blocking layer (not shown in the diagram) are also included in the electron transport layer 43d.

The electron transport layer 43d can be provided as a single layer structure or a laminated structure of a plurality of layers. The electron transport layer 43d may have a single-layer structure formed from one kind or two or more kinds of the materials described below.

In regard to the electron transport layer 43d, as the electron transporting material that constitutes a layer portion adjacent to the light emitting layer 43c (also works as a hole blocking material), any material having a function of transferring the electrons injected from the cathode into the light emitting layer 43c may be acceptable. Regarding such a material, any arbitrary compound can be selected from conventionally known compounds and used.

For example, a nitro-substituted fluorene derivative, a diphenylquinone derivative, a thiopyran dioxide derivative, a carbodiimide, a fleorenylidene methane derivative, anthraquinodimethane, an anthrone derivative, and an oxadiazole derivative may be mentioned. Furthermore, in regard to the oxadiazole derivative, a thiadiazole derivative obtained by substituting the oxygen atom of an oxadiazole ring with a sulfur atom, and a quinoxaline derivative having a quinoxaline ring that is known as an electron-withdrawing group can also be used as the material for the electron transport layer 43d. Furthermore, polymer materials in which these materials have been introduced into the polymer chain, or polymer materials in which these materials are used as the main chains of the polymer can also be used.

Furthermore, metal complexes of 8-quinolinol derivatives, for example, tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, and bis(8-quinolinol)zinc (Znq), and metal complexes in which the central metals of these metal complexes have been substituted by In, Mg, Cu, Ca, Sn, Ga, or Pb, can also be used as the material for the electron transport layer 43d.

In addition to that, a metal-free or metal phthalocyanine, or a compound obtainable by substituting the terminals of such a phthalocyanine with an alkyl group, a sulfonate group or the like, can also be preferably used as the material for the electron transport layer 43d. Furthermore, a distyrylpyrazine derivative that is also used as the material for the light emitting layer 43c, or an inorganic semiconductor such as n-type Si or n-type SiC, that is similar to the material for the hole injection layer 43a or the hole transport layer 43b, can also be used as the material for the electron transport layer 43d.

Furthermore, the n-properties can be enhanced by doping impurities into the electron transport layer 43d. Examples thereof include the materials described in JP 4-297076 A, JP 10-270172 A, JP 2000-196140 A, JP 2001-102175 A, and J. Appl. Phys., 95, 5773 (2004). Furthermore, it is preferable that potassium or a potassium compound is incorporated into the electron transport layer 43d. Regarding the potassium compound, for example, potassium fluoride can be used. When the n-properties of the electron transport layer 43d are enhanced as such, an element of lower power consumption can be produced.

There are no particular limitations on the layer thickness of the electron transport layer 43d; however, the layer thickness is usually about 5 nm to 5 μm, and preferably in the range of 5 to 200 nm.

The electron transport layer 43d can be formed by producing a thin film of any of the above-mentioned materials by a known method such as, for example, a vacuum vapor deposition method, a spin coating method, a casting method, a printing method including an inkjet method, or an LB method.

[Blocking Layers: Hole Blocking Layer and Electron Blocking Layer]

A blocking layer is provided as necessary, in addition to the basic constituent layers of the organic compound thin films described above. For example, there are hole blocking (hole block) layers described in JP 11-204258 A, JP 11-204359A, and “Yuki EL Soshi to Sono Kogyoka Saizensen (Organic EL Elements and Forefront of Industrialization Thereof) (Nov. 30, 1998, published by NTS Publishing, Ltd.)”, p. 237. The layer thickness of the blocking layer is preferably in the range of 3 to 100 nm, and more preferably in the range of 5 to 30 nm.

In a wide sense, a hole blocking layer has the function of the electron transport layer 43d. The hole blocking layer is formed from a hole blocking material having a noticeably low ability of transporting holes while having a function of transporting electrons, and can thus increase the probability of recombination of electrons and holes by blocking holes while transporting electrons. Furthermore, the configuration of the electron transport layer 43d can be used for the hole blocking layer, if necessary. It is preferable that the hole blocking layer is provided adjacently to the light emitting layer 43c.

Meanwhile, in a wide sense, an electron blocking layer has the function of the hole transport layer 43b. The electron blocking layer is formed from a material having a noticeably low ability of transporting electrons while having a function of transporting holes, and can thus increase the probability of recombination of electrons and holes by blocking electrons while transporting holes. Furthermore, the configuration of the hole transport layer 43b can be used for the electron blocking layer, if necessary.

[Encapsulating Member]

The encapsulating member 46 is a plate-shaped (film-like) member covering the top face of the organic EL element 40 and is fixed to the side of the resin base material 11 by means of the adhesive portion 47. The encapsulating member 46 may be an encapsulating film. Such an encapsulating member 46 is provided in a state of covering at least the light emitting unit 43 by exposing the electrode terminal portions of the organic EL element 40. Furthermore, a configuration in which the encapsulating member 46 is provided with an electrode, and conduction is achieved between the electrode terminal portions of the organic EL element 40 and the electrode of the encapsulating member 46, is also desirable.

Specific examples of a plate-shaped (film-like) encapsulating member 46 include a glass substrate, a polymer substrate, and a metal substrate, and these substrates may be produced into a thinner film form and used. Regarding the glass substrate, particularly, soda lime glass, barium/strontium-containing glass, lead glass, aluminosilicate glass, borosilicate glass, barium borosilicate glass, and quartz may be used. Regarding the polymer substrate, polycarbonate, acrylic, polyethylene terephthalate, polyether sulfide, polysulfone, and the like may be used. Examples of the metal substrate include substrates formed from one or more kinds of metals selected from the group consisting of stainless steel, iron, copper, aluminum, magnesium, nickel, zinc, chromium, titanium, molybdenum, silicon, germanium, and tantalum, or alloys thereof.

Particularly, from the viewpoint that the element can be produced into a thin film, it is preferable that a polymer substrate or a metal substrate is processed into a thin film form and used as the encapsulating member.

The substrate material may also be processed into a dented board shape and may be used as an encapsulating member 46. In this case, the substrate member mentioned above is subjected to processing such as sandblast processing or chemical etching processing, and a concave form is formed.

Furthermore, regarding the polymer substrate that has been processed into a film form, it is preferable that the oxygen permeability measured by a method equivalent to JIS K 7126-1987 is 1×10⁻³ ml/(m²·24 h·atm) or less, and the water vapor permeability (25±0.5° C., relative humidity (90±2)% RH) measured by a method equivalent to JIS K 7129-1992 is 1×10⁻³ g/(m²·24 h) or less.

The adhesive portion 47 that fixes the encapsulating member 46 to the resin base material 11 side is used as a sealing agent for encapsulating the gas barrier film 10 and the organic EL element 40 with the encapsulating member 46. Regarding the adhesive portion 47, specifically, a photocurable and thermally curable adhesive having the reactive vinyl group of an acrylic acid-based oligomer or a methacrylic acid-based oligomer, or a moisture-curable adhesive such as 2-cyanoacrylic acid ester may be used.

Regarding the adhesive portion 47, a thermal- and chemical-curable type (mixture of two liquids) adhesive such as an epoxy-based adhesive may be employed. Furthermore, a hot melt type polyamide, a polyester, and a polyolefin may be employed. Also, a cation curing type ultraviolet-curable epoxy resin adhesive may be used.

Regarding the application of the adhesive portion 47 to the adhesion area between the encapsulating member 46 and the gas barrier film 10 may be performed using a commercially available dispenser, or may be printed as in the case of screen printing.

Meanwhile, an organic material that constitutes an organic EL element may be deteriorated by a heat treatment. Therefore, it is preferable that the adhesive portion 47 is capable of adhering and curing at a temperature of from room temperature (25° C.) to 80° C. It is also acceptable that a drying agent is dispersed in the adhesive portion 47.

In a case where a gap is formed between a plate-shaped encapsulating member 46 and the gas barrier film 10, it is preferable that, in a vapor phase and a liquid phase, an inert gas such as nitrogen or argon, or an inert liquid such as a fluorohydrocarbon or a silicon oil is injected into this gap. It is also possible to draw a vacuum. Furthermore, a hygroscopic compound may be encapsulated inside the gap.

Examples of the hygroscopic compound include metal oxides (for example, sodium oxide, potassium oxide, calcium oxide, barium oxide, magnesium oxide, and aluminum oxide), sulfates (for example, sodium sulfate, calcium sulfate, magnesium sulfate, and cobalt sulfate), metal halides (for example, calcium chloride, magnesium chloride, cesium fluoride, tantalum fluoride, cerium bromide, magnesium bromide, barium iodide, and magnesium iodide), and perchloric acids (for example, barium perchlorate and magnesium perchlorate). For the sulfates, metal halides, and perchloric acids, anhydrous salts are suitably used.

Meanwhile, in a case where an encapsulating film is used as the encapsulating member 46, the encapsulating film is provided on the gas barrier film 10 in a state in which the encapsulating film completely covers the light emitting unit 43 in the organic EL element 40, while the electrode terminal portions of the organic EL element 40 are exposed.

Such an encapsulating film is constructed using an inorganic material or an organic material. Particularly, the encapsulating film is constructed from a material having a function of suppressing infiltration of any substance that brings deterioration of the light emitting unit 43 in the organic EL element 40, such as moisture or oxygen. Regarding such a material, for example, an inorganic material such as silicon oxide, silicon dioxide, or silicon nitride is used. Furthermore, in order to ameliorate the vulnerability of the encapsulating film, a film formed from an organic material may be used together with a film formed from any of these inorganic materials, and a laminated structure may be formed.

There are no particular limitations on the method for forming these films, and for example, a vacuum vapor deposition method, a sputtering method, a reactive sputtering method, a molecular beam epitaxy method, a cluster ion beam method, an ion plating method, a plasma polymerization method, an atmospheric pressure plasma polymerization method, a plasma. CVD method, a laser CVD method, a thermal CVD method, or a coating method can be used.

[Protective Member]

Illustration in the diagrams is not shown here; however, a protective member such as a protective film or a protective plate for mechanically protecting the organic EL element 40 may be provided. The protective member is disposed at a position at which the organic EL element 40 and the encapsulating member 46 are sandwiched between the gas barrier film 10 and the protective member. Particularly, in a case where the encapsulating member 46 is an encapsulating film, since mechanical protection for the organic EL element 40 is not sufficient, it is preferable to provide such a protective member.

In regard to the protective member such as described above, a glass plate, a polymer plate, a polymer film that is thinner than this, a metal plate, a metal film that is thinner than this, or a polymeric material film or a metallic material film is applied. Among these, it is particularly preferable to use a polymer film, from the viewpoints of weight reduction and thickness reduction.

[Application of Organic EL Element]

Since the organic EL elements of various configurations described above are planar emitting bodies as described above, the organic EL elements can be used as various luminescent light sources. Examples include lighting apparatuses such as domestic room lightings and vehicle indoor lightings; backlights for watches or liquid crystal displays; illumination for advertisement signboards; light sources for signal lights; light sources for optical storages; light sources for electrophotographic copiers; light sources for optical communication equipment; and light sources for optical sensors. However, the applications are not limited to these, and the organic EL elements can be effectively used particularly for applications such as a backlight of a liquid crystal display device combined with a color filter, and a light source for illumination.

The organic EL element may also be used as a kind of lamp such as a light source for illumination or an exposure light source, and may also be used for a projection device of a type that projects images, or a display device (display) of a type that directly views still images or moving images. In this case, along with the increase in size of illuminating apparatuses and displays in recent years, the light emitting plane may be produced into a large size by so-called tiling, by which light emitting panels provided with organic EL elements are joined in a planar manner.

In the case of using the organic EL element as a display device for replaying moving images, the driving system may be a simple matrix (passive matrix) system or an active matrix. Furthermore, it is possible to produce a color or full-color display device by using two or more kinds of organic EL elements having different luminescent colors.

In the following description, an illuminating apparatus will be described as an example of the applications, and then an illuminating apparatus having a large-sized light emitting plane as a result of tiling will be described.

[Illuminating Apparatus]

An organic EL element can be applied to an illuminating apparatus.

An illuminating apparatus that uses an organic EL element may be designed such that various organic EL elements having the above-mentioned configuration are provided with a resonator structure. In regard to the purpose of use of an organic EL element configured to have a resonator structure, a light source for an optical storage, a light source for an electrophotographic copier, a light source for an optical communication equipment, a light source for an optical sensor, and the like may be considered; however, the purpose of use is not limited to these. The organic EL element may also be used for the applications described above by inducing laser oscillation in the organic EL element.

The material used for the organic EL element can be applied to an organic EL element (also called white organic EL element) that causes substantially white light emission. For example, a plurality of luminescent colors may be emitted by a plurality of luminescent materials, and white luminescence may be obtained as a result of color mixing. The combination of a plurality of luminescent colors may be a combination including three maximum emission wavelengths of three primary colors of red, green, and blue, or may be a combination including two maximum emission wavelengths that utilize the relation of complementary colors such as blue and yellow, or blue-green and orange colors.

Furthermore, the combination of luminescent materials for obtaining a plurality of luminescent colors may be any of a combination of a plurality of materials that emit a plurality of phosphorescent light or fluorescent light, and a combination of a luminescent material that emits fluorescent light or phosphorescent light with a dye material that emits light coming from the luminescent materials as excited light. However, for a white organic EL element, an organic EL element obtained by combining and mixing a plurality of luminescent dopants may also be used.

Such a white organic EL element is such that, unlike the configuration of individually disposing in parallel organic EL elements emitting light of various colors in an array and obtaining white light, the organic EL element itself emits white light. Therefore, a mask is not needed for the formation of most of the layers that constitute the element, and film-forming can be achieved on one surface by a vapor deposition method, a casting method, a spin coating method, an inkjet method, a printing method, or the like. Thus, productivity is also increased.

There are no particular limitations on the luminescent material that is used for the light emitting layers of such a white organic EL element, and for example, in the case of a backlight for a liquid crystal display device, any arbitrary materials may be selected from among the metal complexes described above or known luminescent materials to be suitable for the wavelength ranges corresponding to the CF (color filter) characteristics and combined, so as to constitute white light.

When a white organic EL element as described above is used, an illuminating apparatus that emits substantially white light can be produced.

[Effects of Organic EL Element]

The organic EL element of the embodiment described above has a light extraction layer (light scattering layer 12 and smoothing layer 15) in a gas barrier film 10. Furthermore, a first electrode 41, a light emitting unit 43, and a second electrode 42 are formed on the gas barrier layer 20, in which the Ra of the surface is from 0 nm to 3 nm, and the average of the diameters in the planar direction of the convexities formed on the surface of the gas barrier layer 20 is 50 nm or less. Therefore, the gas barrier layer 20 is highly smooth, and the adverse effects on the organic EL element 40 attributed to the surface unevenness of the light scattering layer 12 are suppressed. Thus, the reliability of an electronic instrument or the like that uses a transparent electroconductive member can be increased. Therefore, the adverse effects on the organic EL element 40 caused by moisture or outgases, and the adverse effects on the organic EL element 40 caused by surface unevenness attributed to the light scattering layer 12 are suppressed, and thus the light extraction efficiency and reliability can be increased.

<6. Method for Producing Organic Electroluminescent Element>

Next, an example of the method for producing the organic EL element 40 as illustrated in FIG. 8 will be described. The method for producing the organic EL element 40 includes, after the various processes for producing a gas barrier film described above, a step of forming a first electrode 41 on the gas barrier layer, a step of forming a light emitting unit 43, and a step of forming a second electrode 42. Regarding the process for producing the gas barrier film 10, processes similar to the method for producing a gas barrier film as described above can be applied. Therefore, in the following description, the step for forming a first electrode 41 on the gas barrier film and the subsequent steps will be disclosed.

[First Electrode Forming Step]

A gas barrier layer 20 that satisfies the requirements that the arithmetic average roughness (Ra) of the surface is from 0 nm to 3 nm, and the average of the diameters in the planar direction of the convexities formed on the surface is 50 nm or larger is formed by the production method described above, and thereby a gas barrier film 10 is formed. Subsequently, a first electrode 41 of the organic EL element 40 is formed using a method similar to the process for forming the electroconductive layer of the transparent electroconductive member as described above. Furthermore, it is also acceptable that, for example, an undercoat layer formed from a compound containing a nitrogen atom is formed on this gas barrier layer 20. For the process of forming the undercoat layer, the technique described in connection with the method for producing a transparent electroconductive member as described above can be applied.

[Light Emitting Unit Forming Step]

Next, a hole injection layer 43a, a hole transport layer 43b, a light emitting layer 43c, an electron transport layer 43d, and an electron injection layer 43e are formed in this order on the first electrode 41, and a light emitting unit 43 is formed. Regarding the method for forming these various layers, a spin coating method, a casting method, an inkjet method, a vapor deposition method, a printing method and the like are available; however, from the viewpoint that it is easy to obtain a uniform film and pinholes are not easily produced, a vacuum vapor deposition method or a spin coating method is particularly preferred. Furthermore, different film-forming methods may be applied respectively for different layers. In the case of employing a vapor deposition method for the formation of these various layers, the vapor deposition conditions may vary depending on the type of the compound used or the like; however, it is preferable that the various conditions are appropriately selected generally within the ranges of a boat heating temperature of 50° C. to 450° C., a degree of vacuum of 1×10⁻⁶ to 1×10⁻² Pa, a vapor deposition speed of 0.01 to 50 nm/sec, a substrate temperature of −50° C. to 300° C., and a layer thickness of 0.1 to 5 μm.

[Second Electrode Forming Step]

After the light emitting unit 43 is formed, a second electrode 42 that serves as a cathode is formed on the top of this unit by an appropriate film-forming method such as a vapor deposition method or a sputtering method. At this time, while the second electrode 42 maintains an insulated state against the first electrode 41 by means of the light emitting unit 43, a pattern is formed from above the light emitting unit 43 into a shape in which terminal portions are drawn out to the peripheral edge of the resin base material 11. Thereby, an organic EL element 40 is obtained. Thereafter, an encapsulating member 46 that covers at least the light emitting unit 43 is provided in a state in which the terminal portions of the extraction electrode 44 and the second electrode 42 in the organic EL element 40 are exposed.

Thus, a desired organic EL element 40 is obtained on a gas barrier film 10. In regard to the production of such an organic EL element 40, it is preferable that members including from the light emitting unit 43 to the second electrode 42 are produced systematically by drawing a vacuum once; however, it does not matter even if the resin base material 11 is taken out from the vacuum atmosphere in the middle of the process and is subjected to another film-forming method. At that time, care needs to be taken, such as that the operation is performed in a dry inert gas atmosphere.

In a case where a direct current voltage is applied to the organic EL element 40 obtained as described above, when the positive polarity is given to the first electrode 41 that serves as an anode, negative polarity is given to the second electrode 42 that serves as a cathode, and a voltage of about 2 to 40 V is applied thereto, light emission can be observed. It is also acceptable that an alternating current voltage is applied. The waveform of the alternating current applied may be any arbitrary form.

### EXAMPLES

Hereinafter, the present invention will be specifically described by way of Examples; however, the present invention is not intended to be limited to these. In the Examples, the symbol “%” will be used, and unless particularly stated otherwise, this symbol represents “percent (%) by mass”

<Production of Organic EL Element of Sample 101>

[Base Material]

(Preparation of Base Material)

A biaxially stretched polyethylene naphthalate film (PEN film, thickness: 100 μm, width: 350 mm, manufactured by DuPont Teijin Films, Ltd., trade name: “TEONEX Q65FA”) was prepared as a resin base material.

(Production of Primer Layer)

A UV-curable organic/inorganic hybrid hard coating material manufactured by JSR Corp., OPSTAR Z7501, was applied on an easily adhesive surface of the resin base material, and the hard coating material was applied with a wire bar such that the layer thickness after drying would be 4 μm. Subsequently, the hard coating material was dried under the dry conditions: 80° C. for 3 minutes, and then in an air atmosphere, curing was performed using a high pressure mercury lamp under the curing conditions: 1.0 J/cm². Thus, a primer layer was formed.

[Production of First Electrode]

The resin base material (50 mm×50 mm) was fixed to a substrate holder of a commercially available vacuum vapor deposition apparatus, and the following compound (1-6) was introduced into a resistance heating boat made of tantalum. These substrate holder and resistance heating boat were attached to a first vacuum chamber of the vacuum vapor deposition apparatus. Furthermore, silver (Ag) was introduced into a resistance heating boat made of tungsten, and the resistance heating boat is attached to the inside of the second vacuum chamber.

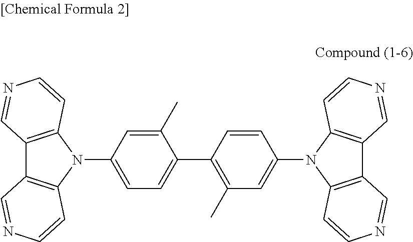 [SMILES: Cc1cc(-n2c3ccncc3c3cnccc32)ccc1-c1ccc(-n2c3ccncc3c3cnccc32)cc1C]

Next, the pressure inside the first vacuum chamber was reduced to 4×10⁻⁴ Pa, and then the resistance heating boat containing compound (1-6) was heated by passing electricity. An undercoat layer of the first electrode formed from compound (1-6) was formed on a substrate at a vapor deposition rate in the range of 0.1 to 0.2 nm/sec. The layer thickness of the undercoat layer was adjusted to 50 nm.

Next, the substrate having the undercoat layer formed thereon was transferred into the second vacuum chamber in a vacuum state. The pressure inside the second vacuum chamber was reduced to 4×10⁻⁴ Pa, and then the resistance heating boat containing silver was heated by passing electricity. An electroconductive layer formed from silver and having a layer thickness of 8 nm was formed on the undercoat layer at a vapor deposition rate in the range of 0.1 to 0.2 nm/sec, and thus a first electrode (positive electrode) having a laminated structure of the undercoat layer and the electroconductive layer was formed.

[Production of Organic Functional Layers]

Into a crucible for vapor deposition in a vacuum vapor deposition apparatus, the constituent materials of the various layers of the organic functional layers were introduced respectively in amounts optimal for the production of the organic EL element. Regarding the crucible for vapor deposition, a crucible produced from a material for resistance heating, such as molybdenum or tungsten, was used.

Regarding the constituent materials for the various layers of the organic functional layers, the following compounds α-NPD, BD-1, GD-1, RD-1, H-1, H-2, and E-1 were used.

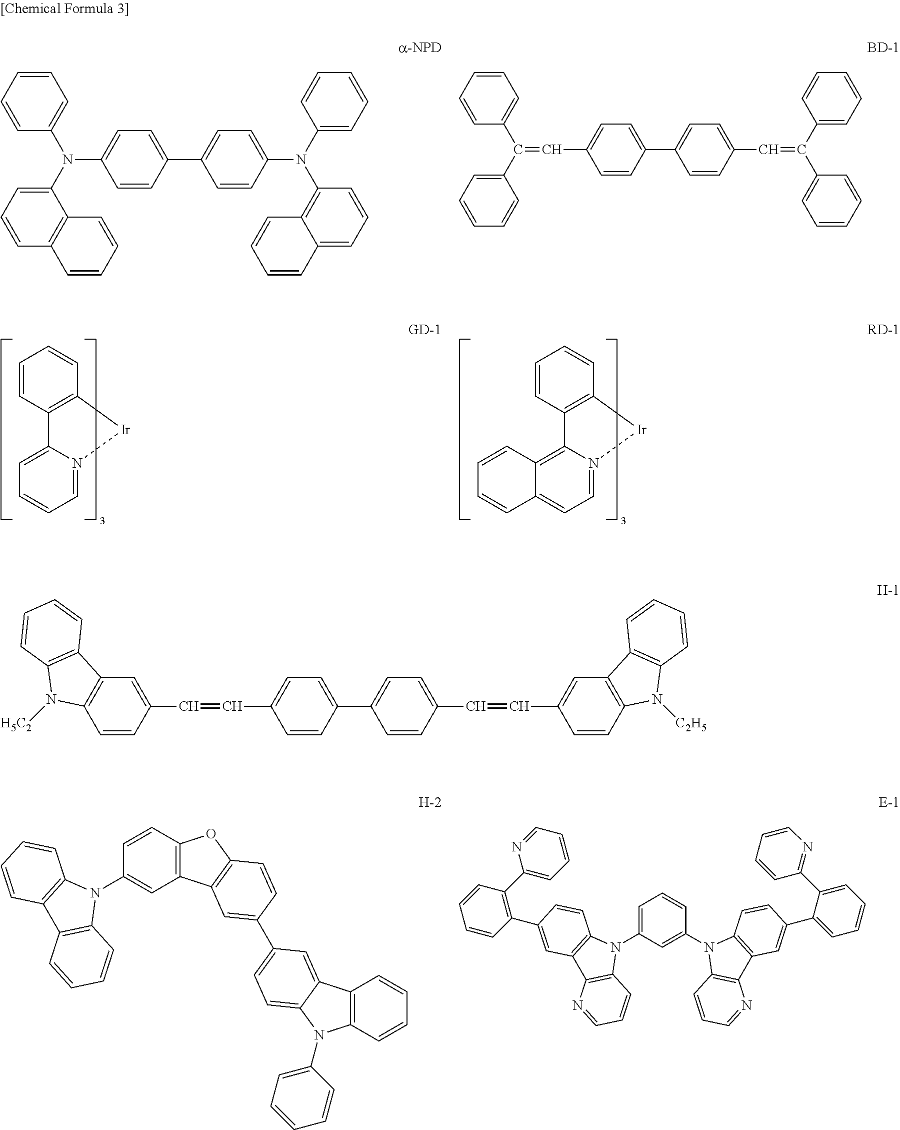

First, the pressure was reduced to obtain a degree of vacuum of 1×10⁻⁴ Pa, a crucible for vapor deposition filled with compound α-NPD was heated by passing electricity, and vapor deposition was carried out on the first electrode at a vapor deposition rate of 0.1 nm/sec. Thus, a hole injection transport layer having a layer thickness of 40 nm was formed.

Similarly, compounds BD-1 and H-1 were co-deposited at a vapor deposition rate of 0.1 nm/sec such that the concentration of compound BD-1 would be 5%, and thus a fluorescent light emitting layer exhibiting blue color and having a layer thickness of 15 nm was formed.

Next, compounds GD-1, RD-1, and H-2 were co-deposited at a vapor deposition rate of 0.1 nm/sec such that the concentration of compound GD-1 would be 17%, and the concentration of compound RD-1 would be 0.8%. Thus, a phosphorescent light emitting layer exhibiting yellow color and having a layer thickness of 15 nm was formed.

Subsequently, compound E-1 was deposited at a vapor deposition rate of 0.1 nm/sec, and an electron transport layer having a layer thickness of 30 nm was formed.

[Production of Counter Electrode]

Furthermore, a layer of lithium fluoride (LiF) having a layer thickness of 1.5 nm was formed, and vapor deposition of aluminum was achieved to a thickness of 110 nm. Thus, a counter electrode (negative electrode) was formed. The counter electrode was formed into a shape in which a terminal portion was shown at the peripheral edge of the substrate, in a state of being insulated by organic functional layers including from the hole injection layer to the electron injection layer.

For the formation of the various layers, a vapor deposition mask was used, and a region having a size of 4.5 cm×4.5 cm positioned at the center of the substrate having a size of 5 cm×5 cm was designated as a light emitting region, and a non-light emitting region having a width of 0.25 cm was provided along the entire periphery of the light emitting region.

[Encapsulation]

(Production of Pressure-Sensitive Adhesive Composition)

100 parts by mass of OPPANOL B50 (manufactured by BASF SE, Mw: 340,000) as a polyisobutylene-based resin, 30 parts by mass of NISSEKI POLYBUTENE GRADE HV-1900 (manufactured by Nippon Oil Corp., Mw: 1,900) as a polybutene resin, 0.5 parts by mass of TINUVIN 765 (manufactured by Ciba Japan K.K., having a tertiary hindered amine group) as a hindered amine-based photostabilizer, 0.5 parts by mass of IRGANOX 1010 (manufactured by Ciba Japan K.K., both of the two β-positions of a hindered phenol group have a tertiary-butyl group) as a hindered phenol-based oxidation inhibitor, and 50 parts by mass of Eastotac H-100L Resin (manufactured by Eastman Chemical Co.) as a cyclic olefin-based polymer were dissolved in toluene, and a pressure-sensitive adhesive composition having a solid content concentration of about 25% by mass was produced.

(Production of Pressure-Sensitive Adhesive Sheet for Encapsulation)

As a gas barrier layer, a polyethylene terephthalate film having aluminum (Al) deposited thereon, ALPET 12/34 (manufactured by Asia Aluminum Holdings, Ltd.), was used, and a solution of the pressure-sensitive adhesive composition thus produced was applied on the aluminum side (gas barrier layer side) such that the layer thickness of the pressure-sensitive adhesive layer formed after drying of the solution would be 20 μm. The pressure-sensitive adhesive composition was dried for 2 minutes at 120° C., and thus a pressure-sensitive adhesive layer was formed. Next, a release-treated polyethylene terephthalate film having a thickness of 38 μm was prepared as a release sheet, and the release-treated surface of the polyethylene terephthalate film was adhered to the pressure-sensitive adhesive layer surface thus formed, and thus a pressure-sensitive adhesive sheet for encapsulation was produced.

(Encapsulation)

The release sheet was removed from the pressure-sensitive adhesive sheet for encapsulation produced by the method described above in a nitrogen atmosphere, and the pressure-sensitive adhesive sheet was dried for 10 minutes on a hot plate that had been heated to 120° C. Subsequently, after it was confirmed that the temperature decreased to room temperature (25° C.), the pressure-sensitive adhesive sheet for encapsulation was laminated so as to completely cover the negative electrode, and the laminated product was heated for 10 minutes at 90° C. An organic EL element of sample 101 was produced in this manner.

<Production of Organic EL Element of Sample 102>

An organic EL element of sample 102 was produced in the same manner as in the case of the sample 101 described above, except that in regard to the production of the sample 101, a first electrode was formed using IZO on the resin base material, using the method described below.

[Production of First Electrode]

The resin base material was transferred to a commercially available parallel flat plate sputtering apparatus equipped with an IZO target, the pressure inside the chamber of the sputtering apparatus was reduced to 5×10⁻³ Pa, and then discharging was performed at a DC output of 500 W while nitrogen gas and oxygen gas were caused to flow. Thus, a first electrode of IZO having a film thickness of 150 nm was formed at a film-forming rate of 10 nm/sec.

<Production of Organic EL Element of Sample 103>

An organic EL element of sample 103 was produced in the same manner as in the case of the sample 101, except that in regard to the production of the sample 101, the first electrode was formed on the resin base material using IGO, using the method described below.

[Production of First Electrode]

The resin base material was transferred to a commercially available parallel flat plate sputtering apparatus equipped with an IGO target, the pressure inside the chamber of the sputtering apparatus was reduced to 5×10⁻³ Pa, and then discharging was performed at a DC output of 500 W while nitrogen gas and oxygen gas were caused to flow. Thus, a first electrode of IGO having a film thickness of 150 nm was formed at a film-forming rate of 10 nm/sec.

<Production of Organic EL Element of Sample 104>

An organic EL element of sample 104 was produced in the same manner as in the case of the sample 101, except that in regard to the production of the sample 101, a layer formed from niobium oxide (NbO) was produced on the resin base material by the method described below, and the first electrode was formed on this layer.

[Niobium Oxide Layer]

A substrate was mounted in a chamber of a magnetron sputtering apparatus (manufactured by Canon Anelva Corp., SPF-730H). Next, the pressure inside the chamber of the magnetron sputtering apparatus was reduced to a reached degree of vacuum of 3.0×10⁻⁴ Pa using an oil-sealed rotary vacuum pump and a cryopump. Niobium oxide (NbOₓ) was used as a target, 20 sccm of argon gas and 3.3 sccm of oxygen gas were introduced, a high frequency electric power (input electric power 1.2 kW) at a frequency of 13.56 MHz was applied, and a niobium oxide (Nb₂O₅) film was formed on the substrate to a film thickness of 30 nm at a film-forming pressure of 0.4 Pa. Thereby, a niobium oxide layer having a refractive index n of 2.34 was formed.

<Production of Organic EL Element of Sample 105>

An organic EL element of sample 105 was produced in the same manner as in the case of the sample 101, except that in regard to the production of the sample 101, a gas barrier layer formed from silicon nitride (SiN) was produced on the resin base material by the method described below, and the first electrode was formed on this layer.

[First Gas Barrier Layer: Silicon Nitride]

A substrate was mounted in a chamber of a magnetron sputtering apparatus (manufactured by Canon Anelva Corp., SPF-730H). Next, the pressure inside the chamber of the magnetron sputtering apparatus was reduced to a reached degree of vacuum of 3.0×10⁻⁴ Pa using an oil-sealed rotary vacuum pump and a cryopump. Si was used as a target, 7 sccm of argon gas and 26 sccm of nitrogen gas were introduced, a high frequency electric power (input electric power 1.2 kW) at a frequency of 13.56 MHz was applied, and a silicon nitride film was formed on the substrate to a film thickness of 300 nm at a film-forming pressure of 0.4 Pa and a film-forming rate of 350 nm/min. Thereby, a first gas barrier layer formed from silicon nitride and having a refractive index n of 1.75 was formed.

<Production of Organic EL Element of Sample 106>

An organic EL element of sample 106 was produced in the same manner as in the case of the sample 105, except that in regard to the production of the sample 105, a gas barrier layer of silicon nitride (SiN) was produced at a film-forming rate of 200 nm/min.

<Production of Organic EL Element of Sample 107>

An organic EL element of sample 107 was produced in the same manner as in the case of the sample 105, except that in regard to the production of the sample 105, a gas barrier layer formed from niobium oxide (Nb₂O₅) (second gas barrier layer) was formed on a gas barrier layer formed from silicon nitride (SiN) (first gas barrier layer; film-forming rate 350 nm/min), and a first electrode was formed on this second gas barrier layer. Meanwhile, the second gas barrier layer formed from niobium oxide (Nb₂O₅) was produced in the same manner as in the case of the niobium oxide layer for the sample 104.

<Production of Organic EL Element of Sample 108>

An organic EL element of sample 108 was produced in the same manner as in the case of the sample 106, except that in regard to the production of the sample 106, a gas barrier layer formed from niobium oxide (Nb₂O₅) (second gas barrier layer) was formed on a gas barrier layer formed from silicon nitride (SiN) (first gas barrier layer; film-forming rate 200 nm/min), and a first electrode was formed on this second gas barrier layer. Meanwhile, the second gas barrier layer formed from niobium oxide (Nb₂O₅) was produced in the same manner as in the case of the niobium oxide layer for the sample 104.

<Production of Organic EL Element of Sample 109>

An organic EL element of sample 109 was produced in the same manner as in the case of the sample 101, except that in regard to the production of the sample 101, a light extraction layer (IES) was produced on the resin base material by the method described below, and a first electrode was formed on this light extraction layer (IES).

[Production of Light Extraction Layer (IES)]

(Production of Light Scattering Layer)

A composition was produced such that the solid content ratio between TiO₂ particles (JR600A manufactured by Tayca Corp.) having a refractive index of 2.4 and an average particle size of 0.25 μm, and a resin solution (230AL (organic inorganic hybrid resin) manufactured by Rasa Industries, Ltd.) was adjusted to 20% by volume/80% by volume, and the solid content concentration of the particles in propylene glycol monomethyl ether (PGME) would be 15% by mass.

An additive (Dispethyk-2096 manufactured by BYK Chemie Japan K.K.) was added thereto in an amount of 0.4% by mass with respect to the solid content (effective mass component), and the composition was formulated at a ratio that gave an amount of 10 ml.

Specifically, the TiO₂ particles, the solvent, and the additive were mixed at a mass ratio of 10% with respect to the TiO₂ particles. While the mixture was cooled to normal temperature (25° C.), the mixture was dispersed for 10 minutes with an ultrasonic dispersing machine (UH-50 manufactured by SMT Corp.) under the standard conditions of a microchip step (MS-3 manufactured by SMT Corp., 3 mmϕ), and thus a dispersion liquid of TiO₂ was produced.

Next, while the TiO₂ dispersion liquid was stirred at 100 rpm, the resin solution was added and mixed thereto in small amounts, and after completion of the addition, the mixture was mixed for 10 minutes after increasing the stirring speed up to 500 rpm. Subsequently, the mixture was filtered through a 0.45-μm hydrophobic PVDF filter (manufactured by Whatman plc), and thus, the desired coating liquid for light scattering layer was obtained.

The coating liquid was applied on a plastic film substrate by an inkjet coating method, and then the coating liquid was subjected to simple drying (70° C., 2 minutes). Furthermore, the applied coating liquid was subjected to a drying treatment for 5 minutes by wavelength-controlled IR that will be described below, under the output power conditions at a base material temperature of below 80° C.

Next, a curing reaction was accelerated under the modification treatment conditions described below, and thus a light scattering layer having a layer thickness of 0.3 μm was obtained. In this manner, a light scattering layer having a refractive index n of 1.66 was produced.

(Modification Treatment Apparatus)

Apparatus: Excimer irradiation apparatus Model MEIRH-M-1-200-222-H-KM-G manufactured by M.D. Com, Inc.

Wavelength: 222 nm

Lamp sealing gas: KrCl

(Modification Treatment Conditions)

Excimer light intensity: 8 J/cm² (222 nm)

Stage heating temperature: 60° C.

Oxygen concentration in irradiation apparatus: atmospheric concentration

(Production of Smoothing Layer)

Next, a coating liquid for a smoothing layer was produced by mixing a high-refractive index UV-curable resin (manufactured by Toyo Ink Co., Ltd., LIODURAS TYT82-01, nanosol particles: TiO2) with an organic solvent including propylene glycol monomethyl ether (PGME) and 2-methyl-2,4-pentanediol (PD) at a solvent ratio of 90% by mass/10% by mass so as to obtain a solid content concentration of 12% by mass, and the composition was formulated at a ratio that gave an amount of 10 ml.

Specifically, the high-refractive index UV-curable resin and a solvent were mixed, and the mixture was mixed for 1 minute at 500 rpm. Subsequently, the mixture was filtered through a 0.2-μm hydrophobic PVDF filter (manufactured by Whatman plc), and thus the desired coating liquid for smoothing layer was obtained.

The coating liquid was applied on the light scattering layer by an inkjet coating method and then was subjected to simple drying (70° C., 2 minutes). Furthermore, the applied coating liquid was subjected to a drying treatment for 5 minutes by wavelength-controlled IR, under the output power conditions at a base material temperature of below 80° C.

The drying treatment was carried out by radiation heat transfer drying by means of a wavelength-controlled infrared heater (two sheets of quartz glass plates that absorb infrared radiation having a wavelength of 3.5 μm or larger is attached to an IR irradiation apparatus (ultimate heater/carbon, manufactured by Meimei Industries, Inc.), and cooling air is caused to flow between the glass plates).

At this time, the cooling air was allowed to flow at 200 L/min, and the tubular surface quartz glass temperature was controlled to be below 120° C. The base material temperature was measured by disposing a K thermocouple respectively at the top and bottom faces of the substrate and at a portion 5 mm away from the top face of the substrate, and connecting the K thermocouples to NR2000 (manufactured by Keyence Corp.).

Next, a curing reaction was accelerated under the modification treatment conditions described below, and a smoothing layer having a layer thickness of 0.5 μm was formed. Thus, a light extraction layer (IES) having a two-layer structure of a light scattering layer and a smoothing layer was produced.

(Modification Treatment Apparatus)

Apparatus: Excimer irradiation apparatus Model MEIRH-M-1-200-222-H-KM-G manufactured by M.D. Com, Inc.

Wavelength: 222 nm

Lamp sealing gas: KrCl

(Modification Treatment Conditions)

Excimer light intensity: 8 J/cm² (222 nm)

Stage heating temperature: 60° C.

Oxygen concentration in irradiation apparatus: atmospheric concentration

<Production of Organic EL Element of Sample 110>

An organic EL element of sample 110 was produced in the same manner as in the case of the sample 109, except that in regard to the production of the sample 109, a gas barrier layer formed from silicon nitride (SiN) was formed on the light extraction layer (IES), and a first electrode was formed on this gas barrier layer. Meanwhile, the gas barrier layer formed from silicon nitride (SiN) was produced in the same manner as in the case of the gas barrier layer formed from silicon nitride (SiN) for the sample 105 (film-forming rate: 350 nm/min).

<Production of Organic EL Element of Sample 111>

An organic EL element of sample 111 was produced in the same manner as in the case of the sample 110, except that in regard to the production of the sample 110, the gas barrier layer formed from silicon nitride (SiN) was formed to have a thickness of 150 nm.

<Production of Organic EL Element of Sample 112>

An organic EL element of sample 112 was produced in the same manner as in the case of the sample 110, except that in regard to the production of the sample 110, a first electrode was formed using IZO. Meanwhile, the first electrode using IZO was produced in the same manner as in the case of the first electrode of the sample 102.

<Production of Organic EL Element of Sample 113>

An organic EL element of sample 113 was produced in the same manner as in the case of the sample 110, except that in regard to the production of the sample 110, a first electrode was formed using IGO. Meanwhile, the first electrode formed using IGO was produced in the same manner as in the case of the first electrode of the sample 103.

<Production of Organic EL Element of Sample 114>

An organic EL element of sample 114 was produced in the same manner as in the case of the sample 109, except that in regard to the production of the sample 109, a gas barrier layer formed from silicon nitride (SiN) was formed on the light extraction layer (IES), and a first electrode was formed on this gas barrier layer. Meanwhile, the gas barrier layer formed from silicon nitride (SiN) was produced in the same manner as in the case of the gas barrier layer formed from silicon nitride (SiN) for the sample 106 (film-forming rate: 200 nm/min).

<Production of Organic EL Element of Sample 115>

An organic EL element of sample 115 was produced in the same manner as in the case of the sample 114, except that in regard to the production of the sample 114, a gas barrier layer formed from silicon nitride (SiN) was formed to have a thickness of 150 nm.

<Production of Organic EL Element of Sample 116>

An organic EL element of sample 116 was produced in the same manner as in the case of the sample 114, except that in regard to the production of the sample 114, a first electrode was formed using IZO. Meanwhile, the first electrode formed using IZO was produced in the same manner as in the case of the first electrode of the sample 102.

<Production of Organic EL Element of Sample 117>

An organic EL element of sample 117 was produced in the same manner as in the case of the sample 114, except that in regard to the production of the sample 114, a first electrode was formed using IGO. Meanwhile, the first electrode formed using IGO was produced in the same manner as in the case of the first electrode of the sample 103.

<Production of Organic EL Element of Sample 118>

An organic EL element of sample 118 was produced in the same manner as in the case of the sample 110, except that in regard to the production of the sample 110, a gas barrier layer formed from niobium oxide (Nb₂O₅) (second gas barrier layer) was formed on a gas barrier layer formed from silicon nitride (SiN) (first gas barrier layer; film-forming rate: 350 nm/min), and a first electrode was formed on this second gas barrier layer. Meanwhile, the second gas barrier layer formed from niobium oxide (Nb₂O₅) was produced in the same manner as in the case of the niobium oxide layer for the sample 104.

<Production of Organic EL Element of Sample 119>

An organic EL element of sample 119 was produced in the same manner as in the case of the sample 114, except that in regard to the production of the sample 114, a gas barrier layer formed from niobium oxide (Nb₂O₅) (second gas barrier layer) was formed on a gas barrier layer formed from silicon nitride (SiN) (first gas barrier layer; film-forming rate: 200 nm/min), and a first electrode was formed on this second gas barrier layer. Meanwhile, the second gas barrier layer formed from niobium oxide (Nb₂O₅) was produced in the same manner as in the case of the niobium oxide layer for the sample 104.

<Evaluation Methods>

For the organic EL elements of samples 101 to 119 thus produced, evaluations of the element characteristics described below were carried out. The evaluation results for the various samples are presented in Table 1.

[Luminescence Efficiency]

For each of the samples thus produced, lighting was performed under constant current density conditions of 2.5 mA/cm² at room temperature (25° C.), and the light emission luminance of each Example was measured using a spectral radiance meter, CS-2000 (manufactured by Konica Minolta, Inc.). Thus, the luminescence efficiency (electric power efficiency) at that current value was determined.

The luminescence efficiency was evaluated by taking the luminescence efficiency of sample 101 as reference, and a sample having a luminescence efficiency of 1.2 times or greater the luminescence efficiency of sample 101 was rated as ◯, and a sample having a luminescence efficiency of less than 1.2 times the luminescence efficiency of sample 101 was rated as ×.

[Long-Term Storability]

Each sample was introduced into a constant temperature chamber at 85° C. (dry), and the voltage increase ratio before storage and after storage at a constant current density similar to that for the luminescence efficiency evaluation was evaluated at certain times. An element that exhibited a voltage increase of greater than 1.0 V from the initiation of the evaluation, or an element in which dark spots having a size of 0.5 mm or larger were generated, were considered unacceptable, and a sample which took a time period of more than 1,000 hours to become unacceptable was rated as ◯, and a sample which took a time period of less than 1,000 hours was rated as ×.

[Operating Life]

For each of the samples thus produced, lighting was performed under constant current density conditions of 15 mA/cm² at room temperature (25° C.), and the light emission luminance of the organic EL element of each sample was measured using a spectral radiance meter, CS-2000 (manufactured by Konica Minolta, Inc.). The front luminance immediately after initiation was designated as 100%, and the time taken for the front luminance to decrease to 70% of the initial luminance (LT70) was designated as operating life. The operating life was calculated by the calculation formula disclosed below. The operating life of the organic EL element of sample 101 was designated as 1.0, and the operating life of each sample was relatively evaluated on the basis of the following criteria.

5: More than 0.9

4: 0.9 or less and more than 0.8

3: 0.8 or less and more than 0.7

2: 0.7 or less and more than 0.6

1: 0.6 or less

(Calculation Formula for Operating Life Equivalent to 1000 Candelas)

Operating life(hours)=t×(x/1000)^{1.6}

t: When the initial luminance at a constant current was designated as 100%, time taken until the luminance decreased to 70%

x: Front luminance (candelas)

Table 1 shows the layer configuration of the base material, light extraction layer, gas barrier layer, and high-refractive index material layer, and the evaluation results for the luminescence efficiency, long-term storability, and operating life for the organic EL elements of the various samples. In Table 1, a resin base material formed from a PEN film is indicated as “PEN”, and the light extraction layer is indicated as “IES”.

TABLE 1

| | | | | | | Long-term | |
|---|---|---|---|---|---|---|---|
| | Gas barrier film layer | | SiN | Nb₂O₅ | Luminescence | storability | Operating |
| Sample | configuration | Electrode | nm (nm/min) | nm | efficiency | (days/85° C.) | life |
| 101 | PEN | Ag | — | — | X | ◯ | 5 |
| 102 | PEN | IZO | — | — | X | ◯ | 5 |
| 103 | PEN | IGO | — | — | X | ◯ | 5 |
| 104 | PEN + Nb₂O₅ | Ag | — | 30 | X | ◯ | 5 |
| 105 | PEN + SiN | Ag | 300 (350 nm/min) | — | X | ◯ | 1 |
| 106 | PEN + SiN | Ag | 300 (200 nm/min) | — | X | ◯ | 4 |
| 107 | PEN + SiN + Nb₂O₅ | Ag | 300 (350 nm/min) | 30 | X | ◯ | 1 |
| 108 | PEN + SiN + Nb₂O₅ | Ag | 300 (200 nm/min) | 30 | X | ◯ | 4 |
| 109 | PEN + IES | Ag | — | — | ◯ | X | 2 |
| 110 | PEN + IES + SiN | Ag | 300 (350 nm/min) | — | ◯ | ◯ | 1 |
| 111 | PEN + IES + SiN | Ag | 150 (350 nm/min) | — | ◯ | X | 1 |
| 112 | PEN + IES + SiN | IZO | 300 (350 nm/min) | — | ◯ | ◯ | 3 |
| 113 | PEN + IES + SiN | IGO | 300 (350 nm/min) | — | ◯ | ◯ | 3 |
| 114 | PEN + IES + SiN | Ag | 300 (200 nm/min) | — | ◯ | ◯ | 4 |
| 115 | PEN + IES + SiN | Ag | 150 (200 nm/min) | — | ◯ | X | 4 |
| 116 | PEN + IES + SiN | IZO | 300 (200 nm/min) | — | ◯ | ◯ | 4 |
| 117 | PEN + IES + SiN | IGO | 300 (200 nm/min) | — | ◯ | ◯ | 4 |
| 118 | PEN + IES + SiN + Nb₂O₅ | Ag | 300 (350 nm/min) | 30 | ◯ | ◯ | 1 |
| 119 | PEN + IES + SiN + Nb₂O₅ | Ag | 300 (200 nm/min) | 30 | ◯ | ◯ | 4 |

As shown in Table 1, samples 109 to 119 that respectively include a light extraction layer (IES) have highly increased luminescence efficiencies, compared to samples 101 to 108 that do not include a light extraction layer (IES). Therefore, it is understood that when an organic EL element includes a light extraction layer (IES), the light extraction efficiency increase to a large extent, irrespective of the presence or absence of a gas barrier layer and the configuration.

Furthermore, sample 109 that has an IES but does not have a gas barrier layer has both low storability and low operating life, compared to samples 101 to 104 that have neither an IES nor a gas barrier layer. From these results, it is understood that the IES has strong adverse effects on the reliability of the organic EL element.

In sample 111 and sample 115, in which the gas barrier layer formed from SiN was formed to have a thickness of 150 nm, storability was deteriorated compared to samples 110 and 114, in which the gas barrier layer formed from SiN was formed to have a thickness of 300 nm. This is speculated to be because when the thickness of the gas barrier layer formed from SiN was 150 nm, sufficient gas barrier properties were not obtained, and deterioration of elements occurred at high temperature. From these results, it is understood that when the thickness of the gas barrier layer formed from SiN is 300 nm or larger, the reliability of the element can be increased.

Furthermore, sample 106, sample 108, samples 114 to 117, and sample 119, in which the gas barrier layer formed from SiN was formed at a film-forming rate of 200 nm/min, satisfied the requirements that the arithmetic average roughness (Ra) of the surface of the gas barrier layer was from 0 nm to 3 nm, and the average of the diameters in the planar direction of the convexities formed on the surface was 50 nm or larger. As an example of a sample in which the gas barrier layer formed from SiN was formed at a film-forming rate of 200 nm/min, a SEM image of the surface of the gas barrier layer of sample 114 is presented in FIG. 2.

Meanwhile, sample 105, sample 107, samples 110 to 113, and sample 118, in which the gas barrier layer formed from SiN was formed at a film-forming rate of 350 nm/min, satisfied the requirement that the arithmetic average roughness (Ra) of the surface was from 0 nm to 3 nm; however, the samples did not satisfy the requirement that the average of the diameters in the planar direction of the convexities formed on the surface was 50 nm or larger. As an example of a sample in which the gas barrier layer formed from SiN was formed at a film-forming rate of 350 nm/min, a SEM image of the surface of the gas barrier layer of sample 110 is presented in FIG. 3.

At the surface of the gas barrier layer of sample 114 shown in FIG. 2, and the surface of the gas barrier layer of sample 110 shown in FIG. 3, the arithmetic average roughness (Ra) values were all 3 nm. That is, sample 110 and sample 114 both satisfy the requirement that the arithmetic average roughness (Ra) is 3 nm or less.

However, at the surface of the gas barrier layer of sample 114 shown in FIG. 2, the diameters in the planar direction of the convexities were distributed in the range of 57 to 101 nm, while at the surface of the gas barrier layer of sample 110 show in FIG. 3, the diameters in the planar direction of the convexities were distributed in the range of 18 to 57 nm.

As described above, due to the film-forming rate, even though the same arithmetic average roughness (Ra) is achieved, there occur large differences in the diameters in the planar direction of the convexities. In sample 106, sample 108, sample 114, and sample 119, all having large diameters in the planar direction of the convexities, the operating life of the organic EL element clearly increased, compared to sample 105, sample 107, sample 110, and sample 118, all having the same configuration except for the surface shape of the gas barrier layer.

From these results, it is understood that as the diameters in the planar direction of convexities are larger, the adverse effects on the organic EL element attributed to the surface shape of the gas barrier layer are reduced, and the operating life of the organic EL element increases. Particularly, even in a configuration having an IES that affects reliability of the organic EL element, when a gas barrier layer which satisfies the requirements that the arithmetic average roughness (Ra) of the surface is from 0 nm to 3 nm and the average of the diameters in the planar direction of the convexities formed on the surface is 50 nm or larger is included, reliability of the organic EL element can be secured.

As described above, in regard to an organic EL element having a light extraction layer (IES), when the organic EL element includes a gas barrier layer which satisfies the requirements that the arithmetic average roughness (Ra) of the surface is from 0 nm to 3 nm and the average of the diameters in the planar direction of the convexities formed on the surface is 50 nm or larger, storability and the operating life of the organic EL element can be further increased. Therefore, an organic EL element having excellent reliability and excellent light extraction efficiency can be constructed.

The present invention is not intended to be limited to the configurations described in the exemplary embodiments described above, and various changes and modifications can be made as long as the constitution of the present invention is maintained

### REFERENCE SIGNS LIST

10: gas barrier film

11: resin base material

12: light scattering layer

13: light scattering particles

14: binder

15: smoothing layer

20: gas barrier layer

21: first gas barrier layer

22: second gas barrier layer

30: transparent electroconductive member

31: electroconductive layer

40: organic EL element

41: first electrode

42: second electrode

43: light emitting unit

43a: hole injection layer

43b: hole transport layer

43c: light emitting layer

43d: electron transport layer

43e: electron injection layer

44: extraction electrode

45: auxiliary electrode

46: encapsulating member

47: adhesive portion

50: base material

51: feed-out roller

52, 53, 54, 55: conveying roller

56: winding roller

57, 58: film-forming roller

60: gas supply port

61: power supply for plasma generation

62, 63: magnetic field generating apparatus

1. A gas barrier film comprising:
a resin base material;
a light scattering layer provided on the resin base material;
a smoothing layer provided on the light scattering layer; and
a gas barrier layer provided on the smoothing layer,
wherein the arithmetic average roughness (Ra) of the surface of the gas barrier layer is from 0 nm to 3 nm, and the average of the diameters in the planar direction of the convexities formed on the surface of the gas barrier layer is 50 nm or larger.

2. The gas barrier film according to claim 1, wherein the gas barrier layer includes at least one or more selected from silicon nitride and silicon oxynitride.

3. The gas barrier film according to claim 2, wherein the gas barrier layer has a first gas barrier layer including one or more selected from silicon nitride and silicon oxynitride, and a second gas barrier layer including niobium oxide.

4. A transparent electroconductive member comprising:
the gas barrier film according to claim 1; and
an electroconductive layer provided on the gas barrier layer of the gas barrier film.

5. The transparent electroconductive member according to claim 4, wherein the gas barrier layer includes at least one or more selected from silicon nitride and silicon oxynitride.

6. The transparent electroconductive member according to claim 5, wherein the gas barrier layer has a first gas barrier layer including one or more selected from silicon nitride and silicon oxynitride, and a second gas barrier layer including niobium oxide.

7. An organic electroluminescence element comprising:
the gas barrier film according to claim 1;
a first electrode provided on the gas barrier layer of the gas barrier film;
a light emitting unit provided on the first electrode; and
a second electrode provided on the light emitting unit.

8. The organic electroluminescence element according to claim 7, wherein the gas barrier layer includes at least one or more selected from silicon nitride and silicon oxynitride.

9. The organic electroluminescence element according to claim 8, wherein the gas barrier layer has a first gas barrier layer including one or more selected from silicon nitride and silicon oxynitride, and a second gas barrier layer including niobium oxide.

10. A method for producing the gas barrier film according to claim 1, the method comprising:
forming the light scattering layer on the resin base material;
forming the smoothing layer on the light scattering layer; and
forming the gas barrier layer on the smoothing layer using a dry process at a film-forming rate of from 150 nm/min to 250 nm/min.

11. The method for producing a gas barrier film according to claim 10, wherein the gas barrier layer including silicon nitride is formed using a plasma chemical vapor deposition (CVD) method.

12. The method for producing a gas barrier film according to claim 11, wherein the method includes, as the forming a gas barrier layer, forming a first gas barrier layer including silicon nitride using a plasma CVD method; and forming a second gas barrier layer including niobium oxide using a sputtering method.

13. A method for producing a gas barrier film, the method comprising:
forming a light scattering layer on a resin base material;
forming a smoothing layer on the light scattering layer;
forming a first gas barrier layer including silicon oxynitride on the smoothing layer by modifying a polysilazane; and
forming a second gas barrier layer including niobium oxide on the first gas barrier layer using a sputtering method.

14. A method for producing the transparent electroconductive member according to claim 4, the method comprising:
forming the light scattering layer on the resin base material;
forming the smoothing layer on the light scattering layer;
forming the gas barrier layer on the smoothing layer at a film-forming rate of from 150 nm/min to 250 nm/min; and
forming the electroconductive layer on the gas barrier layer.

15. A method for producing a transparent electroconductive member, the method comprising:
forming a light scattering layer on a resin base material;
forming a smoothing layer on the light scattering layer;
forming a first gas barrier layer including silicon oxynitride on the smoothing layer by modifying a polysilazane;
forming a second gas barrier layer including niobium oxide on the first gas barrier layer using a sputtering method; and
forming an electroconductive layer on the second gas barrier layer.

16. A method for producing the organic electroluminescence element according to claim 7, the method comprising:
forming the light scattering layer on the resin base material;
forming the smoothing layer on the light scattering layer;
forming the gas barrier layer on the smoothing layer at a film-forming rate of from 150 nm/min to 250 nm/min;
forming the first electrode on the gas barrier layer;
forming the light emitting unit on the first electrode; and
forming the second electrode on the light emitting unit.

17. A method for producing an organic electroluminescence element, the method comprising:
forming a light scattering layer on a resin base material;
forming a smoothing layer on the light scattering layer;
forming a first gas barrier layer including silicon oxynitride on the smoothing layer by modifying a polysilazane; and
forming a second gas barrier layer including niobium oxide on the first gas barrier layer using a sputtering method;
the method further comprising:
forming a first electrode on the second gas barrier layer;
forming a light emitting unit on the first electrode; and
forming a second electrode on the light emitting unit.
